(19) United States
(12) Patent Application Publication
(10) Pub. No.: US 2026/0353782 A1
(43) Pub. Date: Nov. 5, 2026

(54) SEMICONDUCTOR DEVICE INCLUDING INTERLAYER INSULATING LAYER HAVING AN EMBEDDED PORTION EXTENDING INTO ACTIVE PATTERN

(71) Applicant: SAMSUNG ELECTRONICS CO., LTD., Suwon-si (KR)

(72) Inventors: Woohyeon CHOI, Suwon-si (KR); Myungil Kang, Suwon-si (KR); Jehyoung Koo, Suwon-si (KR); Kyunam Park, Suwon-si (KR); Wooseok Park, Suwon-si (KR); Hyewon Song, Suwon-si (KR); Doyoung Choi, Suwon-si (KR)

(73) Assignee: SAMSUNG ELECTRONICS CO., LTD., Suwon-si (KR)

(21) Appl. No.: 19/402,483

(22) Filed: Nov. 26, 2025

(30) Foreign Application Priority Data
May 2, 2025 (KR) 10-2025-0057971

(51) Int. Cl. H10D 84/83; H10D 30/00; H10D 30/43; H10D 62/10; H10D 62/13; H10D 62/60; H10D 64/23; H10D 30/01; H10D 84/01

(52) U.S. Cl. CPC H10D 84/833; H10D 30/43; H10D 30/502; H10D 62/121; H10D 62/151; H10D 62/60; H10D 64/256; H10D 30/014; H10D 30/0191; H10D 84/0147; H10D 84/0151

(57) ABSTRACT

A semiconductor device includes active patterns on a substrate and spaced apart in a first direction, at least one source/drain pattern on at least a first active pattern of the active patterns, an interlayer insulating layer covering the at least one source/drain pattern, and a separation pattern between the active patterns and extending in a second direction intersecting the first direction, where the interlayer insulating layer includes an embedded portion extending into the first active pattern of the active patterns, the separation pattern includes a first sidewall and a second sidewall opposite to the first sidewall in the first direction and the first sidewall contacts the embedded portion and the second sidewall contacts the at least one source/drain pattern.

### CROSS-REFERENCE TO RELATED APPLICATIONS

This application is based on and claims priority to Korean Patent Application No. 10-2025-0057971, filed on May 02, 2025, in the Korean Intellectual Property Office, the disclosure of which are is incorporated by reference herein in its entirety.

### BACKGROUND

The present disclosure relates to a semiconductor and a method for manufacturing the same, and in particular, to a semiconductor device including a field effect transistor (FET) and a method for manufacturing the same.

Semiconductor devices may include integrated circuits including a metal oxide semiconductor FET (MOSFET). To meet an increasing demand for semiconductor devices with a small pattern size and a reduced design rule, a size of MOSFET has also been scaled down. The scale-down of the MOSFETs may lead to deterioration in operational properties of the semiconductor devices. A variety of studies are being conducted to overcome technical limitations associated with the scale-down of the semiconductor devices and to realize high performance semiconductor devices.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device that may have improved reliability and electrical characteristics, and a method of manufacturing the same.

Additional aspects will be set forth in part in the description which follows and, in part, will be apparent from the description, or may be learned by practice of the presented embodiments.

According to an aspect of an example embodiment, a semiconductor device may include active patterns on a substrate and spaced apart in a first direction, at least one source/drain pattern on at least a first active pattern of the active patterns, an interlayer insulating layer covering the at least one source/drain pattern, and a separation pattern between the active patterns and extending in a second direction intersecting the first direction, where the interlayer insulating layer includes an embedded portion extending into the first active pattern of the active patterns, the separation pattern includes a first sidewall and a second sidewall opposite to the first sidewall in the first direction and the first sidewall contacts the embedded portion and the second sidewall contacts the at least one source/drain pattern.

According to an aspect of an example embodiment, a semiconductor device may include an active pattern on a substrate, a source/drain pattern on the active pattern, a capping insulating layer covering the source/drain pattern, an interlayer insulating layer on the capping insulating layer, and a separation pattern on the substrate and extending in a first direction, where the interlayer insulating layer includes an embedded portion extending into the active pattern, the capping insulating layer includes an embedded layer between the embedded portion and the separation pattern, and a bottom surface of the embedded layer is at a level that is the same as a level of a bottom surface of the source/drain pattern.

According to an aspect of an example embodiment, a semiconductor device may include a substrate including an active pattern, a device isolation pattern defining the active pattern, at least one first channel pattern and a second channel pattern on the active pattern and spaced apart in a first direction, a first source/drain pattern and a second source/drain pattern respectively connected to the at least one first channel pattern and the second channel pattern, a separation pattern on the substrate and extending in a second direction intersecting the first direction, a gate electrode on the at least one first channel pattern and the second channel pattern, a gate insulating layer between the gate electrode, the at least one first channel pattern and the second channel pattern, a capping insulating layer covering the first source/drain pattern and the second source/drain pattern, a gate capping pattern on an upper surface of the gate electrode, an interlayer insulating layer covering the first source/drain pattern, the second source/drain pattern and the capping insulating layer, an active contact connected to the first source/drain pattern and the second source/drain pattern through the interlayer insulating layer, a gate contact connected to the gate electrode through the gate capping pattern and the interlayer insulating layer, and a first metal layer on the interlayer insulating layer, the first metal layer including a first wiring connected to the active contact and the gate contact, where the interlayer insulating layer includes an embedded portion extending into the active pattern, the capping insulating layer comprises an embedded layer extending between the embedded portion and the separation pattern, and the separation pattern is between the embedded portion and the second source/drain pattern.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a plan view illustrating a semiconductor device according to one or more embodiments;

FIG. 2A is a cross-sectional view taken along line A-A′ in FIG. 1;

FIG. 2B is a cross-sectional view taken along line B-B′ of FIG. 1;

FIG. 2C is a cross-sectional view taken along line C-C′ of FIG. 1;

FIG. 3A is an enlarged view illustrating a portion M of FIG. 2A according to one or more embodiments;

FIG. 3B is a plan view illustrating a semiconductor device according to one or more embodiments;

FIG. 3C is a cross-sectional view taken along line D-D′ of FIG. 3B; and

FIGS. 4, 5, 6, 7A, 7B, 8, 9, 10A, 10B, 11, 12A, 12B, 13, 14, 15, 16A, 16B, 17, 18A, 18B, 19A, 19B, 20, 21A, 21B and 21C are diagrams illustrating a method of manufacturing a semiconductor device according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, "at least one of a, b, and c," should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Terms such as first, second, etc. may be used to describe various components, but are used only for the purpose of distinguishing one component from another component. These terms do not limit the difference in the material or structure of the components.

The terms of a singular form may include plural forms unless otherwise specified. In addition, when a certain part “includes” a certain component, it means that other components may be further included rather than excluding other components unless otherwise stated.

The use of the term “the” and similar designating terms may correspond to both the singular and the plural.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

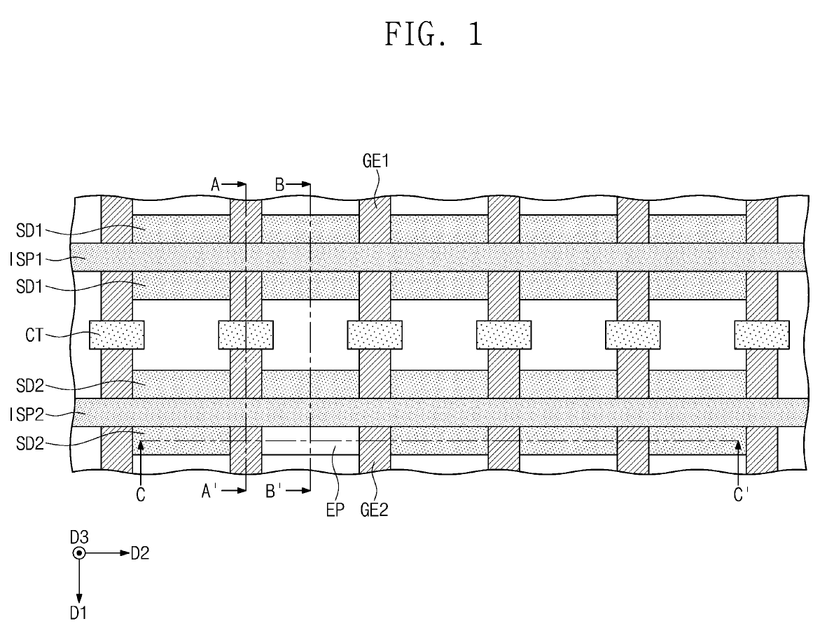

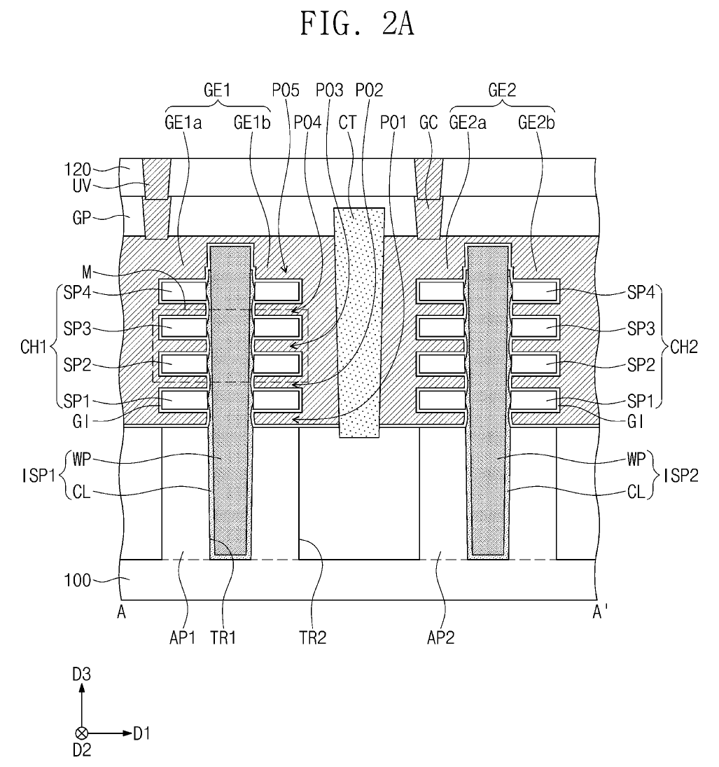

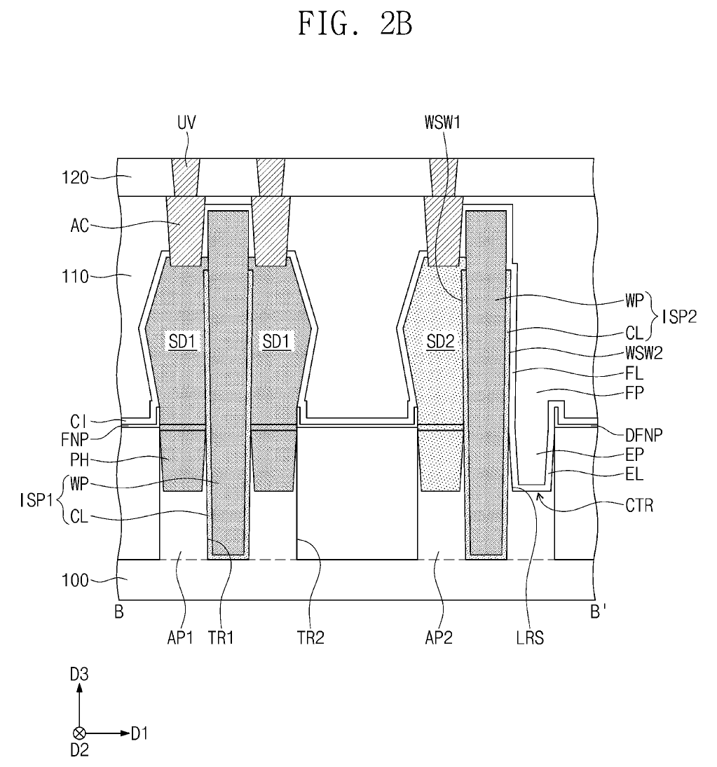

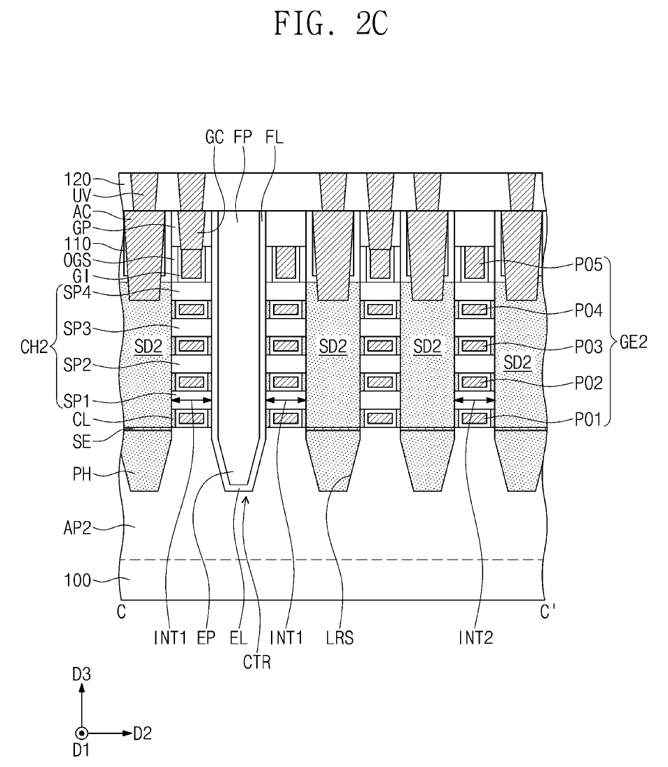

FIG. 1 is a plan view illustrating a semiconductor device according to one or more embodiments. FIGS. 2A, 2B and 2C are views illustrating a semiconductor device according to one or more embodiments, and are cross-sectional views taken along line A-A′, line B-B′, and line C-C′ respectively in FIG. 1.

Referring to FIGS. 1, 2A, 2B and 2C, a semiconductor device may include a substrate 100. A plurality of logic transistors constituting a logic circuit may be disposed on the substrate 100. For example, the substrate 100 may be an insulating substrate including a silicon-based insulating layer. For example, the substrate 100 may include at least one of silicon oxide, silicon nitride, and silicon oxynitride.

The substrate 100 may extend along a plane defined by a first direction D1 and a second direction D2. The first direction D1 and the second direction D2 may intersect with each other and be parallel to an upper surface of the substrate 100. For example, the first direction D1 and the second direction D2 may be orthogonal to each other.

First active patterns AP1 and second active patterns AP2 may be defined by first and second trenches TR1, TR2 in the substrate 100. For example, each of the first active patterns AP1 or the second active patterns AP2 may be defined by the first trenches TR1, and the first active patterns AP1 and the second active patterns AP2 may be defined by the second trenches TR2. The first active patterns AP1 and the second active patterns AP2 may be part of the substrate 100. For example, the first active patterns AP1 and the second active patterns AP2 may be part of the substrate 100 protruding in a third direction D3 perpendicular to the upper surface of the substrate 100. However, for convenience of description, the substrate 100 and the first and second active patterns AP1 and AP2 are defined to be different elements.

Each of the first active patterns AP1 and the second active patterns AP2 may extend in the second direction D2. The first active patterns AP1 and the second active patterns AP2 may be spaced apart from each other in the first direction D1 by a device isolation pattern ST to be described later. The first active patterns AP1 or the second active patterns AP2 may be spaced apart from each other in the first direction D1 by separation patterns ISP1 and ISP2 to be described later.

The device isolation pattern ST may be provided on the substrate 100. The device isolation pattern ST may fill the second trenches TR2. In a plan view, the device isolation pattern ST may surround the first and second active patterns AP1 and AP2. An upper surface of the device isolation pattern ST may be coplanar with upper surfaces of the first and second active patterns AP1 and AP2, but is not limited thereto. For example, the device isolation pattern ST may include an insulating material such as silicon oxide.

A first channel pattern CH1 and a second channel pattern CH2 may be provided on each of the first and second active patterns AP1 and AP2. The first channel pattern CH1 and the second channel pattern CH2 may be adjacent to each other in the first direction D1. The first channel pattern CH1 and the second channel pattern CH2 may be spaced apart from each other in the first direction D1 by the separation patterns ISP1 and ISP2 interposed therebetween. That is, as shown in FIG. 2A, a separation pattern ISP1 may be between sides of the semiconductor patterns SP1-SP4 within the channel pattern CH1 and similarly with channel pattern CH2. A plurality of the first channel patterns CH1 and the second channel patterns CH2 may be provided, and may be spaced apart from each other in the second direction D2.

Each of the first and second channel patterns CH1 and CH2 may include a first semiconductor pattern SP1, a second semiconductor pattern SP2, a third semiconductor pattern SP3, and a fourth semiconductor pattern SP4. The first to fourth semiconductor patterns SP1, SP2, SP3, and SP4 may be spaced apart from each other in a vertical direction (e.g., the third direction D3). For example, the first to fourth semiconductor patterns SP1, SP2, SP3, and SP4 may include crystalline silicon. Each of the first to fourth semiconductor patterns SP1, SP2, SP3, and SP4 may be a nanosheet. In some embodiments, the number of semiconductor patterns of the first and second channel patterns CH1 and CH2 may be variously provided. The separation patterns (ISP1/ISP2) may extend between each of the semiconductor patterns of a respective channel pattern.

First source/drain patterns SD1 may be provided on the first active pattern AP1, and second source/drain patterns SD2 may be provided on the second active pattern AP2. The first source/drain patterns SD1 on the first active pattern AP1 may be provided on a sidewall of a first separation pattern ISP1. The second source/drain patterns SD2 on the second active pattern AP2 may be provided on a sidewall of the second separation pattern ISP2. The first and second source/drain patterns SD1, SD2 are located on both sidewalls of the first and second channel patterns CH1, CH2, and may be electrically connected to the first and second channel patterns CH1, CH2.

The first source/drain patterns SD1 may include impurity regions having a first conductivity type (e.g., p-type). The second source/drain patterns SD2 may include impurity regions having a second conductivity type (e.g., n-type). For example, the first and second source/drain patterns SD1 and SD2 may include impurity regions having the same conductivity type, or include impurity regions having different conductivity types from each other.

The first and second source/drain patterns SD1 and SD2 may include a seed pattern SE and a contact sacrificial pattern PH. The contact sacrificial pattern PH may be a part of the first and second source/drain patterns SD1 and SD2 embedded in the first and second active patterns AP1, AP2. The contact sacrificial pattern PH may include a material having an etch selectivity with respect to the first and second active patterns AP1, AP2.

The seed pattern SE may be provided on the contact sacrificial pattern PH. Each of the first and second source/drain patterns SD1 and SD2 may be an epitaxial pattern formed by a selective epitaxial growth process (SEG) using the seed pattern SE as seeds. For example, the first and second source/drain patterns SD1 and SD2 may include any one of silicon and silicon-germanium.

A first gate electrode GE1 may be provided on the first active patterns AP1, and a second gate electrode GE2 may be provided on the second active patterns AP2. The first gate electrode GE1 may be provided on the first channel pattern CH1 of the first active patterns AP1. The second gate electrode GE2 may be provided on the second channel pattern CH2 of the second active patterns AP2. For example, the first gate electrode GE1 may surround each of the first to fourth semiconductor patterns SP1, SP2, SP3, and SP4 of the first channel pattern CH1, and the second gate electrode GE2 may surround each of the first to fourth semiconductor patterns SP1, SP2, SP3, and SP4 of the second channel pattern CH2. The first gate electrode GE1 and the second gate electrode GE2 may be spaced apart in the first direction D1 by cutting patterns CT to be described later.

Each of the first and second gate electrodes GE1 and GE2 may include first to fourth inner electrodes PO1, PO2, PO3, and PO4 and an outer electrode PO5. Each of the first to fourth inner electrodes PO1, PO2, PO3, and PO4 may be positioned between the first semiconductor pattern SP1 and the first or second active patterns AP1 and AP2 and between the first to fourth semiconductor patterns SP1, SP2, SP3, and SP4. The outer electrode PO5 may be on the fourth semiconductor pattern SP4, which is the uppermost semiconductor pattern among the first to fourth semiconductor patterns SP1, SP2, SP3, and SP4. For example, the first and second gate electrodes GE1 and GE2 may include at least one of a metal material (e.g., Ti, Mo, W, Cu, Al, Ta, Ru, Ir, Co, etc.), a metal nitride (e.g., a nitride such as Ti, Mo, W, Cu, A1, Ta, Ru, Ir, Co, etc.), and impurity-doped polysilicon.

The separation patterns ISP1 and ISP2 may be provided on the substrate 100. In a plan view, each of the separation patterns ISP1 and ISP2 extends in the second direction D2, and the separation patterns ISP1 and ISP2 may be spaced apart from each other in the first direction D1. The separation patterns ISP1 and ISP2 may include a first separation pattern ISP1 and a second separation pattern ISP2. The first separation pattern ISP1 may be provided on the first active pattern AP1, and the second separation pattern ISP2 may be provided on the second active pattern AP2. For example, the separation patterns ISP1 and ISP2 may include an insulating material such as silicon oxide, silicon nitride, silicon oxynitride, and silicon oxycarbide (SiOC). In some embodiments, the separation patterns ISP1 and ISP2 may be composed of a single layer or a multilayer including different insulating materials.

The separation patterns ISP1 and ISP2 may be located in the first trench TR1. The separation patterns ISP1 and ISP2 may have a pillar shape extending in the third direction D3. The first separation pattern ISP1 may be located between the sides of the first active pattern AP1, and the second separation pattern ISP2 may be located between the sides of the second active pattern AP2. The first separation pattern ISP1 may extend between the sides of the first active pattern AP1, and the second separation pattern ISP2 may extend between the sides of the second active patterns AP2. The first separation pattern ISP1 may be positioned between the first channel patterns CH1 adjacent to each other in the first direction D1, and the second separation pattern ISP2 may be positioned between the second channel patterns CH2 adjacent to each other in the first direction D1.

The first gate electrode GE1 may include a first electrode portion GE1a and a second electrode portion GE1b. The first and second electrode portions GE1a and GE1b of the first gate electrode GE1 may be located on the first channel pattern CH1. For example, the first and second electrode portions GE1a and GE1b may surround three faces of each of the first to fourth semiconductor patterns SP1, SP2, SP3, and SP4 of the first channel pattern CH1.

In some embodiments, the first electrode portion GE1a and the second electrode portion GE1b of the first gate electrode GE1 may be spaced apart from each other in the first direction D1 by the first separation pattern ISP1. For this reason, the first electrode portion GE1a and the second electrode portion GE1b of the first gate electrode GE1 may be electrically insulated from each other. Therefore, the first channel patterns CH1 adjacent to the first separation pattern ISP1 may constitute different logic transistors from each other.

The second gate electrode GE2 may include a first electrode portion GE2a and a second electrode portion GE2b. The first and second electrode portions GE2a and GE2b may be located on the second channel pattern CH2. For example, the first and second electrode portions GE2a and GE2b of the second gate electrode GE2 may surround three faces of each of the first to fourth semiconductor patterns SP1, SP2, SP3, and SP4 of the second channel pattern CH2.

In some embodiments, the first electrode portion GE2a and the second electrode portion GE2b of the second gate electrode GE2 may be spaced apart from each other in the first direction D1 by the second separation pattern ISP2. For this reason, the first electrode portion GE2a and the second electrode portion GE2b of the second gate electrode GE2 may be electrically insulated from each other. Therefore, the second channel patterns CH2 adjacent to the second separation pattern ISP2 may constitute different logic transistors from each other.

A gate insulating layer GI may be provided between the first and second gate electrodes GE1 and GE2 and the first to fourth semiconductor patterns SP1, SP2, SP3, and SP4 of the first and second channel patterns CH1 and CH2. The gate insulating layer GI may cover an upper surface, a bottom surface, and one sidewall of each of the first to fourth semiconductor patterns SP1, SP2, SP3, and SP4. The gate insulating layer GI may cover both sidewalls of an upper portion of the separation patterns ISP1 and ISP2. The gate insulating layer GI may be interposed between the first separation pattern ISP1 and the first gate electrode GE1 and between the second separation pattern 1SP2 and the second gate electrode GE2. The gate insulating layer GI may extend between the first and second gate electrodes GE1 and GE2 and the device isolation pattern ST. The gate insulating layer GI may extend between the first and second gate electrodes GE1 and GE2 and the first and second active patterns AP1 and AP2. The gate insulating layer GI may also be positioned between the outer electrode PO5 and outer gate spacers OGS to be described later.

The gate insulating layer GI may include silicon oxide, silicon oxynitride, and/or a high dielectric constant material. Herein, the high dielectric constant material may be a material having a higher dielectric constant than silicon oxide.

A pair of the outer gate spacers OGS may be provided on both sides of the outer electrode PO5 of the first and second gate electrodes GE1 and GE2. For example, the outer gate spacers OGS may include at least one of SiON, SiCN, SiOCN, or SiN. In addition, the outer gate spacers OGS may be composed of a single layer or a multilayer having different insulating materials.

A fence portion FNP may be provided on a lower sidewall of each of the first and second source/drain patterns SD1 and SD2. The fence portion FNP may be provided on the device isolation pattern ST. The fence portion FNP may be a portion of the outer gate spacers OGS. The fence portion FNP may include at least one of SiON, SiCN, SiOCN, or SiN.

Gate capping patterns GP may be provided on the first and second gate electrodes GE1 and GE2. The gate capping patterns GP may cover an upper surface of the outer electrode PO5 of the first and second gate electrodes GE1 and GE2. For example, the gate capping patterns GP may include at least one of SiON, SiCN, SiOCN, or SiN.

A first interlayer insulating layer 110 may be provided on the substrate 100. The first interlayer insulating layer 110 may cover the first and second source/drain patterns SD1 and SD2. An upper surface of the first interlayer insulating layer 110 may be substantially coplanar with upper surfaces of the gate capping patterns GP. For example, the first interlayer insulating layer 110 may include an insulating material such as silicon oxide.

A capping insulating layer CI may be provided between the first interlayer insulating layer 110 and the first and second source/drain patterns SD1 and SD2. The capping insulating layer CI may extend on the device isolation pattern ST and cover surfaces of the first and second source/drain patterns SD1 and SD2. The capping insulating layer CI may cover the fence portion FNP. For example, the capping insulating layer CI may include an insulating material different from a material of the first interlayer insulating layer 110. In some embodiments, the capping insulating layer CI may be formed of a single layer or a multilayer including different insulating materials.

Active contacts AC may be provided in the first interlayer insulating layer 110. The active contacts AC may penetrate a portion of the first interlayer insulating layer 110 along the third direction D3. Each of the active contacts AC may be connected to corresponding first and second source/drain patterns SD1 and SD2. For example, the active contacts AC may include at least one of a metal material (e.g., Ti, Mo, W, Cu, Al, Ta, Ru, Ir, Co, etc.) and a metal nitride (e.g., a nitride such as Ti, Mo, Wi, Cu, Al, Ta, Ru, Ir, Co, etc.). In some embodiments, a further separation pattern comprising an insulating material may be provided between the active contacts AC. In some embodiments, a silicide pattern may be provided between the active contacts AC and the first and second source/drain patterns SD1 and SD2.

Gate contacts GC may be provided in the gate capping patterns GP. The gate contacts GC may be connected to the first and second gate electrodes GE1 and GE2 through the gate capping patterns GP along the third direction D3. For example, the gate contacts GC may include at least one of a metal material (e.g., Ti, Mo, W, Cu, Al, Ta, Ru, Ir, Co, etc.) and a metal nitride (e.g., a nitride such as Ti, Mo, Wi, Cu, Al, Ta, Ru, Ir, Co, etc.).

The cutting patterns CT may be provided between the first and second gate electrodes GE1 and GE2. The cutting patterns CT may extend in the third direction D3 between adjacent first and second gate electrodes GE1 and GE2. The cutting patterns CT may penetrate an upper portion of the device isolation pattern ST. For example, each of the cutting patterns CT may have a vertical length that is greater than a vertical length of each of the first and second gate electrodes GE1 and GE2. For this reason, the first and second gate electrodes GE1 and GE2 may be spaced apart from each other in the first direction D1 by the cutting patterns CT.

A second interlayer insulating layer 120 may be provided on the first interlayer insulating layer 110. The second interlayer insulating layer 120 may cover the first interlayer insulating layer 110, the gate capping patterns GP, the active contacts AC, and the gate contacts GC. The second interlayer insulating layer 120 may include substantially the same insulating material as the first interlayer insulating layer 110.

Upper vias UV may be provided in the second interlayer insulating layer 120. The upper vias UV may penetrate the second interlayer insulating layer 120. Each of the upper vias UV may be connected with corresponding the active contacts AC and the gate contacts GC. For example, the upper vias UV may include a metal material (e.g., Ti, Mo, W, Cu, Al, Ta, Ru, Ir, Co, etc.).

In some embodiments, a metal layer including wiring patterns and via patterns may be provided on the upper vias UV. The wiring patterns and the via patterns of the metal layer may be electrically connected to the upper vias UV. Adjacent logic transistors may exchange electrical signals with one another through the metal layer. A plurality of the metal layers may be provided, and may be stacked on each other in the third direction D3.

In some embodiments, a power transfer network layer may be provided on a bottom surface of the substrate 100. For example, the power transfer network layer may include a wiring network for applying a source voltage. Alternatively, the power transfer network layer may include a wiring network for applying a drain voltage. In some embodiments, the power transfer network layer may include wiring patterns and via patterns. The wiring patterns and the via patterns may be stacked in the third direction D3 to be electrically connected to each other.

A backside active contact may be provided between the power transfer network layer and the first and second source/drain patterns SD1 and SD2. The backside active contact may be connected to at least one of the first and second source/drain patterns SD1 and SD2. The backside active contact may be electrically connected with the wiring patterns and the via patterns of the power transfer network layer. For this reason, at least one of the first and second source/drain patterns SD1 and SD2 may be electrically connected to the power transfer network layer. For example, the backside active contact may include at least one of a metal material (e.g., Ti, Mo, W, Cu, Al, Ta, Ru, Ir, Co, etc.) or a metal nitride (e.g., a nitride of Ti, Mo, Wi, Cu, Al, Ta, Ru, Ir, Co, etc.).

The first interlayer insulating layer 110 and the capping insulating layer CI will be described in more detail with reference to FIGS. 1, 2A, 2B and 2C.

A cutting region CTR may be provided on the second active pattern AP2. The cutting region CTR may be a portion where the first and second source/drain patterns SD1 and SD2 are not formed on the first and second active patterns AP1 and AP2. Instead of forming the first and second source/drain patterns SD1 and SD2, the cutting region CTR may include an embedded portion EP and an embedded layer EL to be described later. Hereinafter, the embedded portion EP and the embedded layer EL may be formed only on the second active pattern AP2, but embodiments are not limited thereto. For example, the embedded portion EP and the embedded layer EL may be formed on the first active pattern AP1.

The first source/drain patterns SD1 may be provided on both sidewalls of the first separation pattern ISP1 on the first active pattern AP1, respectively. The second source/drain pattern SD2 may be provided on a first sidewall WSW1 of the second separation pattern ISP2. The first interlayer insulating layer 110 may be provided on a second sidewall WSW2 of the second separation pattern ISP2 instead of the second source/drain pattern SD2. The first and second sidewalls WSW1 and WSW2 may face each other in the first direction D1. The second separation pattern ISP2 may be provided between the second source/drain pattern SD2 and the first interlayer insulating layer 110.

The capping insulating layer CI may include the embedded layer EL interposed between the embedded portion EP and the second active pattern AP2. The embedded layer EL may be a portion of the capping insulating layer CI that extends into the second active pattern AP2. The embedded layer EL may cover an inner wall of a lower recess LRS formed on the second active pattern AP2. A bottom surface of the embedded layer EL may be located at substantially the same level as the bottom surface of the second source/drain pattern SD2. A thickness of the embedded layer EL may be about 3 nm to about 10 nm, and in some embodiments about 3 nm to about 8 nm.

The capping insulating layer CI may include a filling layer FL extending between the second separation pattern ISP2 and the first interlayer insulating layer 110. The filling layer FL may be provided on the embedded layer EL. In other words, the filling layer FL may be a portion of the capping insulating layer CI extending along a sidewall of the second separation pattern ISP2.

The first interlayer insulating layer 110 may include a filling portion FP covering a sidewall of the second separation pattern ISP2 and an embedded portion EP extending into the second active pattern AP2. The embedded portion EP may be provided on the embedded layer EL to fill a remaining portion of the lower recess LRS. The filling portion FP may be provided on the embedded portion EP. The filling layer FL may be interposed between the filling portion FP and the second separation pattern ISP2.

A width of the embedded portion EP in the first direction D1 and a width of the embedded portion EP in the second direction D2 may decrease toward the bottom surface of the substrate 100 in the vertical direction. The width of the embedded portion EP may have a minimum value at a bottom surface of the embedded portion EP. A level of the bottom surface of the embedded portion EP may be higher than a level of the bottom surface of the second source/drain pattern SD2.

The contact sacrificial pattern PH of the second source/drain pattern SD2 may be provided on one sidewall of a lower portion of the second separation pattern ISP2, and the embedded portion EP may be provided on the other sidewall of the lower portion of the second separation pattern ISP2. The second source/drain pattern SD2 may be provided on one sidewall of an upper portion of the second separation pattern ISP2, and the filling portion FP may be provided on the other sidewall of the upper portion of the second separation pattern ISP2.

The filling portion FP and the filling layer FL may be interposed between the second channel patterns CH2 that are spaced apart from each other in the second direction D2. For example, the filling portion FP and the filling layer FL may be interposed between the first semiconductor patterns SP1 spaced apart from each other in the second direction D2. The filling portion FP and the filling layer FL may be interposed between the second semiconductor patterns SP2 spaced apart from each other in the second direction D2. The filling portion FP and the filling layer FL may be interposed between the third semiconductor patterns SP3 spaced apart from each other in the second direction D2. The filling portion FP and the filling layer FL may be interposed between the fourth semiconductor patterns SP4 spaced apart from each other in the second direction D2. The filling layer FL may contact sidewalls of the first to fourth semiconductor patterns SP1, SP2, SP3, and SP4. The filling layer FL may contact a cladding pattern CL to be described later.

The filling portion FP and the filling layer FL may be interposed between the second source/drain patterns SD2 spaced apart from each other in the second direction D2. A first interval INT1 between the filling layer FL and the second source/drain pattern SD2 adjacent to each other may be the same as a second interval INT2 between the second source/drain patterns SD2 adjacent to one another in the second direction D2. That is, the interval between the filling layer FL and the source/drain patterns adjacent to the filling layer FL may be the same as the interval between source/drain patterns that are adjacent to each other and are not directly adjacent to the filling layer FL. The first interval INT1 may be a distance in the second direction D2 between the filling layer FL and the second source/drain pattern SD2. The second interval INT2 may be a distance in the second direction D2 between a sidewall of the second source/drain pattern SD2 and a sidewall of another second source/drain pattern SD2. The first interval INT1 and the second interval INT2 may be the same as widths of the first to fourth semiconductor patterns SP1, SP2, SP3, and SP4 in the second direction D2.

The filling portion FP and the filling layer FL may extend in the third direction D3. An upper surface of the filling portion FP and an upper surface of the filling layer FL may be coplanar with each other. The upper surface of the filling portion FP and the upper surface of the filling layer FL may be coplanar with an upper surface of the gate capping pattern GP. The upper surface of the filler FP and the upper surface of the filling layer FL may be positioned at the same level as an upper surface of the active contact AC.

Even if the second source/drain pattern SD2 is not formed on the second active pattern AP2, a dummy fence portion DFNP may be formed on the cutting region CTR. Therefore, the dummy fence portion DFNP may not cover the sidewall of the second source/drain pattern SD2 and may be surrounded by the first interlayer insulating layer 110. The capping insulating layer CI may surround the dummy fence portion DFNP. The capping insulating layer CI may be interposed between the dummy fence portion DFNP and the first interlayer insulating layer 110.

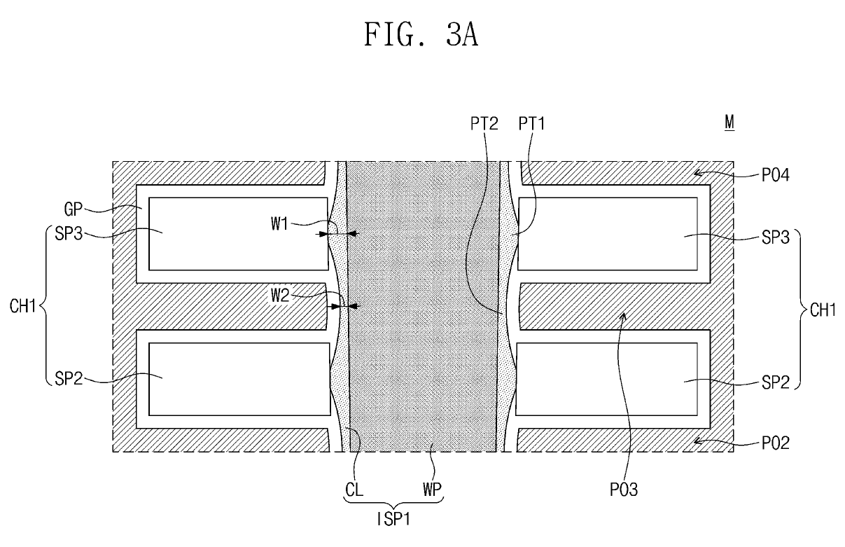

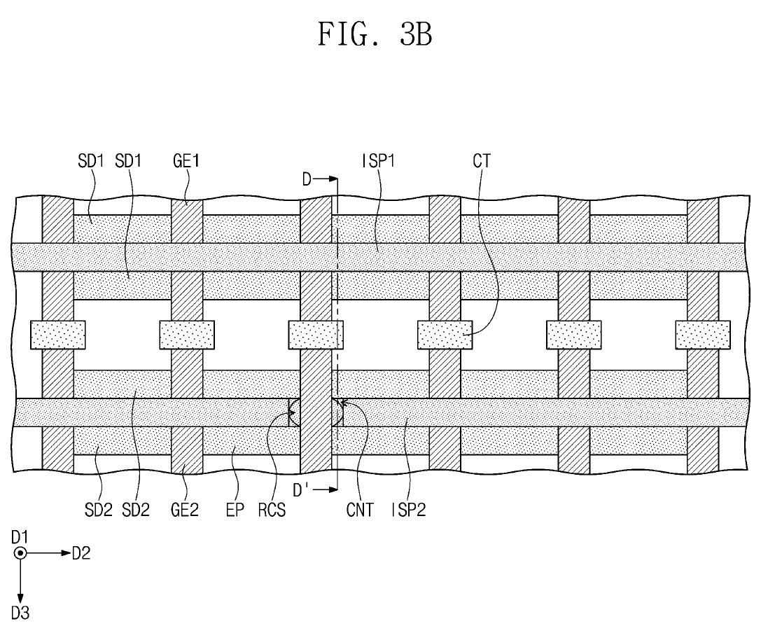

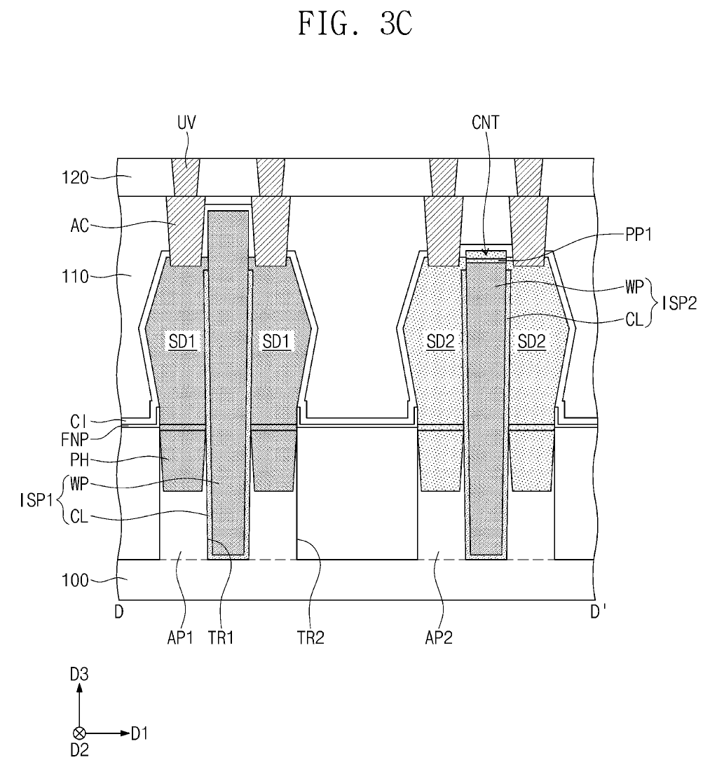

FIG. 3A is an enlarged view illustrating a portion M of FIG. 2A according to one or more embodiments. The separation patterns ISP1 and ISP2 will be described in more detail with reference to FIG. 3A.

The separation patterns ISP1 and ISP2 may include the cladding pattern CL and a separation wall pattern WP on the cladding pattern CL. The cladding pattern CL may cover both sidewalls and a bottom surface of the separation wall pattern WP. An upper surface of the cladding pattern CL may be lower than or at a same level as an upper surface of the separation wall pattern WP. A width of the cladding pattern CL in the first direction D1 may be smaller than a width of the separation wall pattern WP in the first direction D1. In some embodiments, the cladding pattern CL may not be provided on a portion of the sidewall of the separation wall pattern WP.

The cladding pattern CL may include materials having different etch selectivity with respect to the separation wall pattern WP. The separation wall pattern WP may include, but is not limited to, an insulating material such as silicon oxide, silicon nitride, and silicon oxynitride. The cladding pattern CL may include, but is not limited to, at least one of SiON, SiCN, SiOCN, or SiN. For example, the separation wall pattern WP may include SiO2, and the cladding pattern CL may include SiN.

The cladding pattern CL may include a first portion PT1 provided between the separation wall pattern WP and the first channel pattern CH1 and a second portion PT2 interposed between the separation wall patterns WP and the gate electrode GE. A middle portion of the first portion PT1 may contact sidewalls of the first channel pattern CH1. An edge portion of the first portion PT1 may be spaced apart from sidewalls of the first channel pattern CH1. The gate insulating layer GI may be interposed between the edge portion of the first portion PT1 and the first channel pattern CH1. A gate insulating layer GI may be interposed between the second portion PT2 and the gate electrode GE.

A first width W1 of the first portion PT1 in the first direction D1 may be greater than a second width W2 of the second portion PT2 in the first direction D1. The first width W1 has a maximum value at the middle portion of the first portion PT1 and may decrease toward the edge portion of the first portion PT1. The second width W2 may have a minimum value at a middle portion of the second portion PT2 and increase toward an edge portion of the second portion PT2. The second portion PT2 may have a concave profile, but is not limited thereto. In other words, the first portion PT1 may contact the semiconductor patterns, and the second portion PT2 may be spaced apart from the electrodes of the gate electrode in the first direction D1.

Referring again to FIGS. 2A, 2B and 2C, the cladding pattern CL may be interposed between the separation wall pattern WP and the embedded portion EP and between the separation wall pattern WP and the filling portion FP. The cladding pattern CL may be interposed between the separation wall pattern WP and the embedded layer EL and between the separation wall pattern WP and the filling layer FL. The embedded layer EL may extend between the cladding pattern CL and the embedded portion EP, and the filling layer FL may extend between the cladding pattern CL and the filling portion FP. The filling layer FL may contact the cladding pattern CL. At least a portion of the embedded layer EL may contact the cladding pattern CL. For example, an upper portion of the embedded layer EL may contact the cladding pattern CL, and a lower portion of the embedded layer EL may also be spaced apart from the cladding patterns CL. The distance between the embedded layer EL and the cladding pattern CL may increase toward the bottom surface of the embedded layer EL.

On the other hand, when the first and second source/drain patterns SD1 and SD2 are formed on the sidewalls of the separation patterns ISP1 and ISP2, the cladding pattern CL may contact the sidewalls of the first and second sources/drain patterns SD1 and SD2.

FIGS. 3B and 3C are diagrams illustrating a semiconductor device according to one or more embodiments. FIG. 3B is a plan view for describing a semiconductor device according to one or more embodiments. FIG. 3C is a cross-sectional view taken along line D-D′ of FIG. 3B.

According to FIGS. 3B and 3C, the first and second active patterns AP1 and AP2 may be separated by etching the separation patterns ISP1 and ISP2. The separation patterns ISP1 and ISP2 may be etched more than intended, thereby forming a recess region RCS. The etched separation patterns ISP1 and ISP2 may include recessed sidewalls that are concavely etched.

According to a manufacturing method to be described later, a first sacrificial pattern PP1 may be formed on the separation patterns ISP1 and ISP2. In this case, the first sacrificial pattern PP1 may include silicon (Si). During the epitaxial growth (SEG) process for forming the first and second source/drain patterns SD1 and SD2, epitaxial growth SEG may be performed together based on the first sacrificial pattern PP1. For this reason, the connection pattern CNT, which is an epitaxial pattern, may also be formed on upper surfaces of the separation patterns ISP1 and ISP2.

As a result, the first and second source/drain patterns SD1 and SD2, which should be spaced apart by the separation patterns ISP1 and ISP2, may not be spaced apart and upper portions of the separation patterns ISP1 and ISP2 may contact each other by the connection pattern CNT, and an electrical short may occur. The first and second source/drain patterns SD1 and SD2 and the gate electrode GE formed after removing the first sacrificial pattern PP1 may meet with each other, and an electrical short may occur.

According to one or more embodiments, the first and second active patterns AP1 and AP2 may be separated by not forming the first and second source/drain patterns SD1, SD2 on the first and second activated patterns AP1, AP2, respectively. Therefore, since the separation patterns ISP1 and ISP2 are not etched, the first and second source/drain patterns SD1 and SD2 may be prevented from meeting each other or prevent the gate electrode GE and the first and second sources/drain patterns SD1 and SD2 from meeting each other to cause an electrical short.

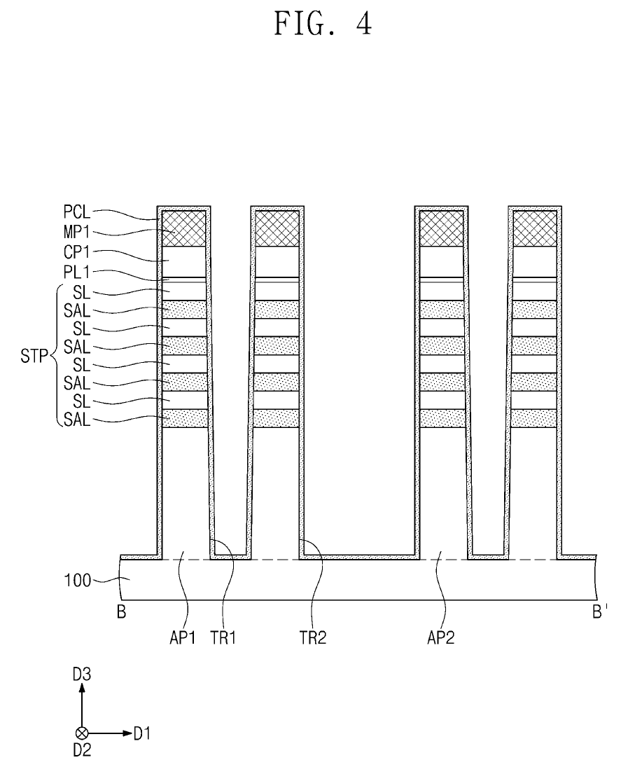

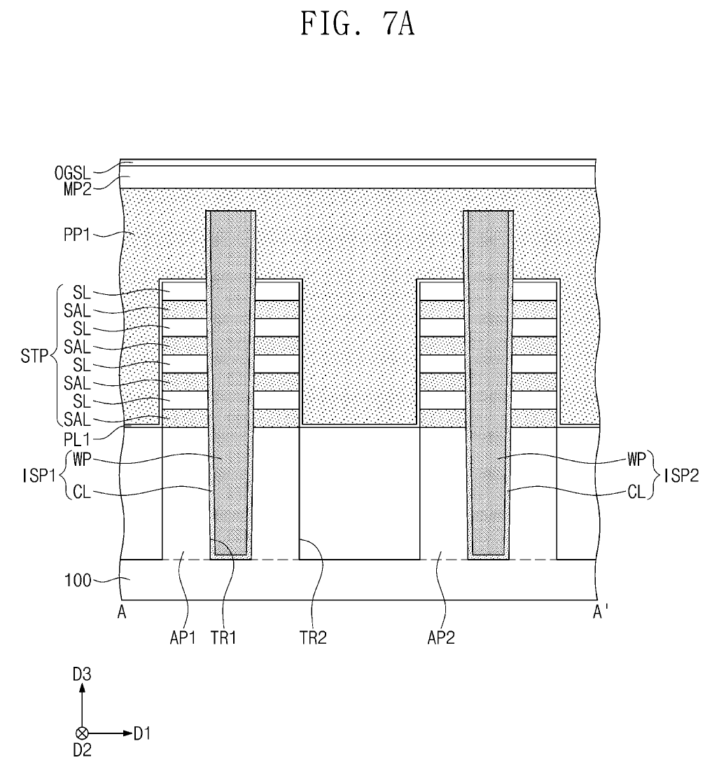

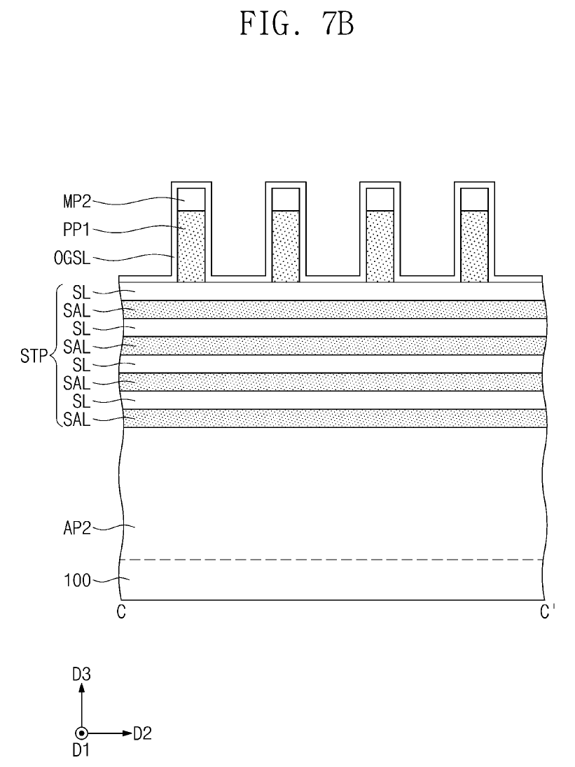

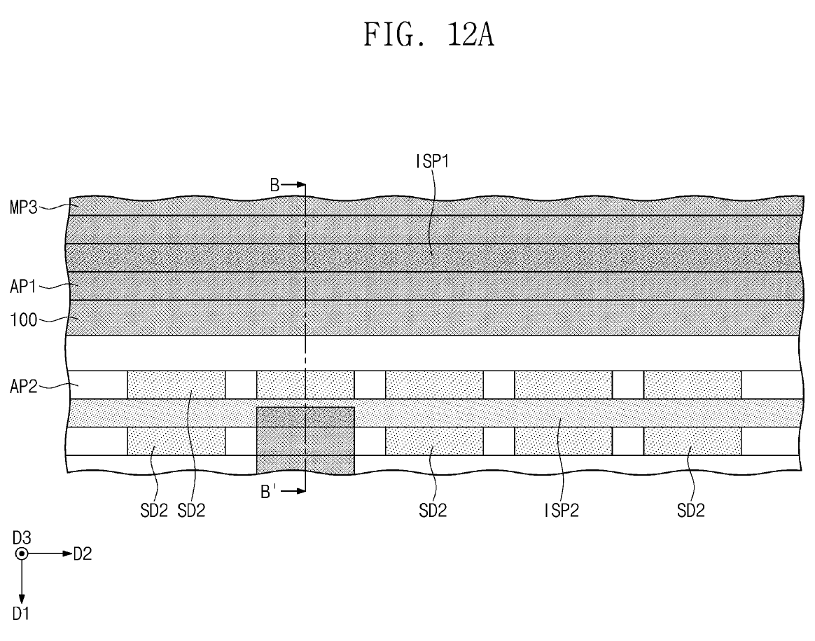

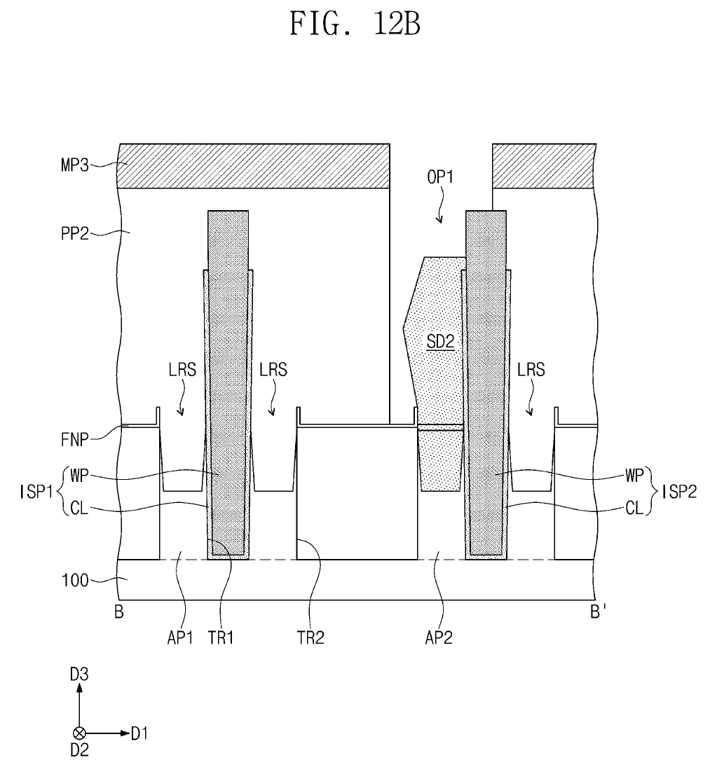

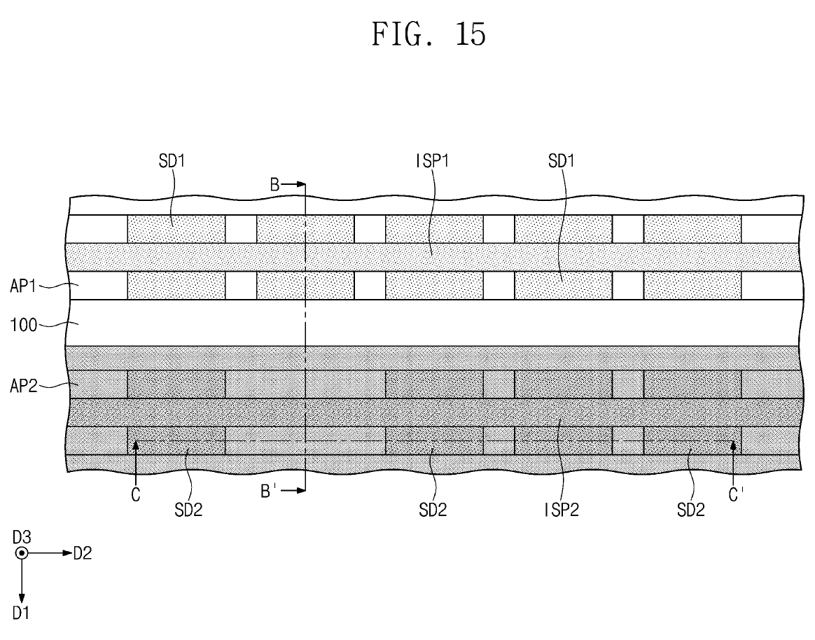

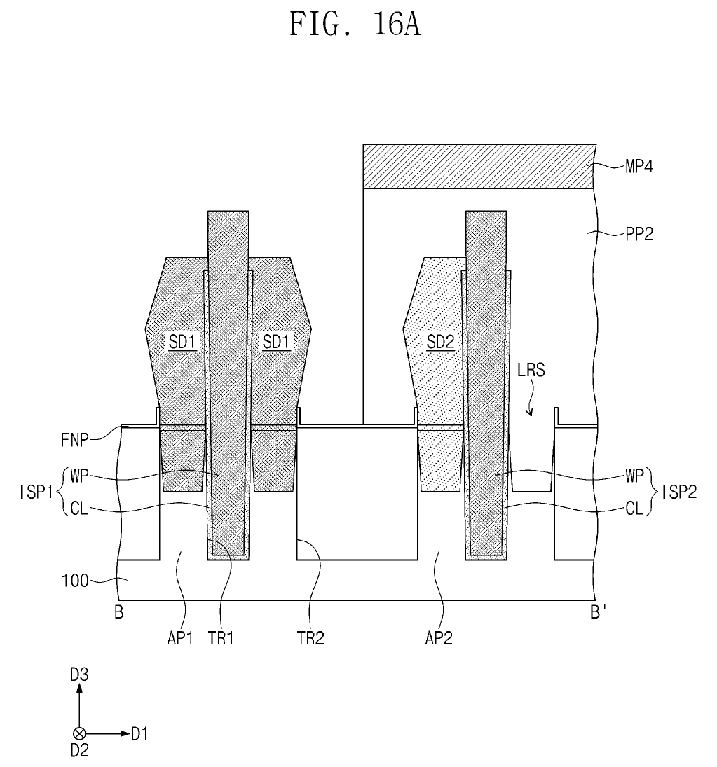

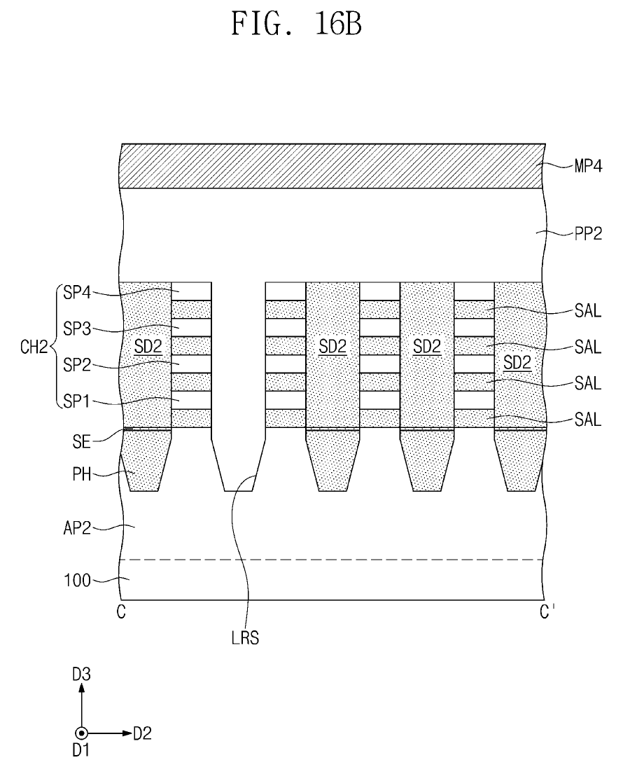

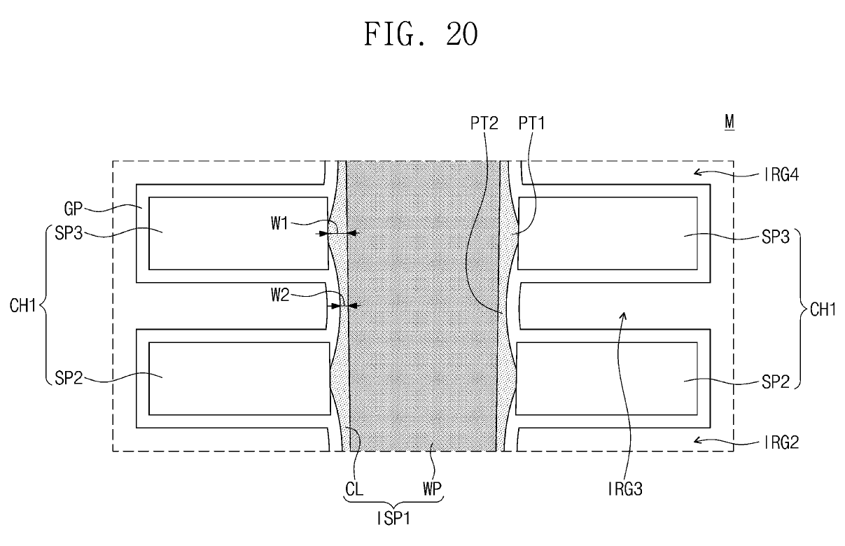

FIGS. 4, 5, 6, 7A, 7B, 8, 9, 10A, 10B, 11, 12A, 12B, 13, 14, 15, 16A, 16B, 17, 18A, 18B, 19A, 19B, 20, 21A, 21B and 21C are diagrams illustrating a method of manufacturing a semiconductor device according to one or more embodiments. FIGS. 7A, 19A, and 21A are cut along line A-A′ of FIG. 1. FIGS. 4, 5, 6, 9, 10A, 11, 13, 14, 17, 18A and 21B are cut along line B-B′ of FIG. 1. FIG. 12B is a cut along line B-B′ of FIG. 12A, and FIGS. 16A and 16B are cut along lines B-B′ and C-C′ of FIG. 15A, respectively. FIGS. 7B, 8, 10B, 18B, 19B and 21C are cut along line C-C′ of FIG. 1. FIG. 20 is an enlarged view of portion M of FIG. 2A.

Referring to FIG. 4, the substrate 100 may be provided. For example, the substrate 100 may be a substrate including silicon, germanium, silicon-germanium, or may be a compound semiconductor substrate.

Stacking patterns STP, a first protective layer PL1, and a first capping pattern CP1 may be sequentially formed on the substrate 100. The stacking patterns STP may include semiconductor layers SL and sacrificial layers SAL alternately stacked along the third direction D3. The sacrificial layers SAL may include a material that may have an etch selectivity with respect to the semiconductor layers SL. In the process of removing the sacrificial layers SAL described later, the semiconductor layers SL may not be removed or may be removed in a small amount. For example, the semiconductor layers SL may include any one of silicon, germanium, and silicon-germanium, and the sacrificial layers SAL may include the other one of silicon, germanium, and silicon-germanium. The first protective layer PL1 may include an insulating material. The first capping pattern CP1 may include silicon-germanium.

A first mask pattern MP1 may be formed on the first capping pattern CP1. The first mask pattern MP1 may include a material having an etching selectivity with respect to the first capping pattern CP1. For example, the first mask pattern MP1 may include silicon nitride.

Forming the stacking patterns STP, the first protective layer PL1, and the first capping pattern CP1 may include alternately forming the semiconductor layers SL and the sacrificial layers SAL on the substrate 100, forming the first protective layer PL1 and the first capping pattern CP1, and performing a patterning process using the first mask pattern MP1 as a mask. An upper portion of the substrate 100 may be removed together by the patterning process. As a result, the first and second trenches TR1 and TR2 defining the first and second active patterns AP1 and AP2 may be formed. The first trenches TR1 may have a relatively larger aspect ratio than the second trenches TR2. Each of the first and second active patterns AP1 and AP2 may extend along the second direction D2.

A preliminary cladding layer PCL may be conformally formed on the substrate 100. The preliminary cladding layer PCL may cover sidewalls of each of the stacking patterns STP, the first protective layer PL1, the first capping pattern CP1, and the first mask pattern MP1. The preliminary cladding layer PCL may cover inner walls of each of the first trench TR1 and the second trench TR2. The preliminary cladding layer PCL may be formed to have a uniform thickness. The preliminary cladding layer PCL may include, but is not limited to, at least one of SiON, SiCN, SiOCN, or SiN. For example, the preliminary cladding layer PCL may include an insulating material such as silicon nitride.

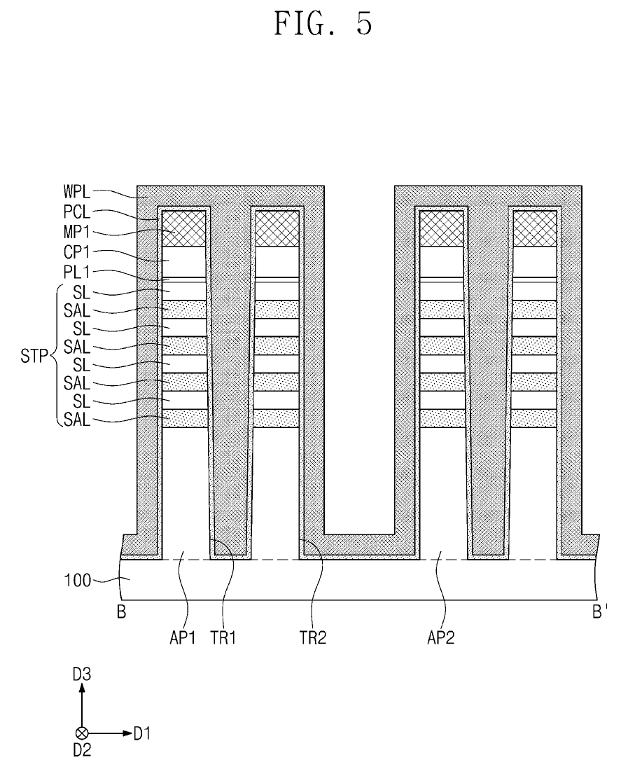

Referring to FIG. 5, a separation wall layer WPL may be formed on the preliminary cladding layer PCL. The separation wall layer WPL may be formed to fill the first trenches TR1. In some embodiments, due to a large aspect ratio of the first trenches TR1, a seam or an air gap may be formed inside the separation wall layer WPL.

The separation wall layer WPL may not fill the second trenches TR2. A thickness of the separation wall layer WPL may be greater than a thickness of the preliminary cladding layer PCL. The separation wall layer WPL may include, but is not limited to, an insulating material such as silicon oxide, silicon nitride, and silicon oxynitride. For example, the separation wall layer WPL may include SiO2.

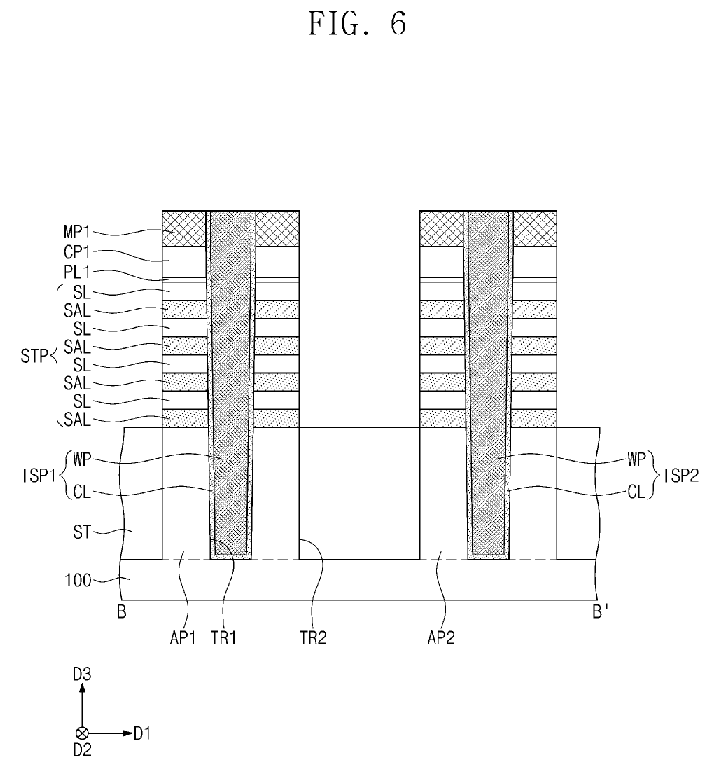

Referring to FIG. 6, the separation patterns ISP1 and ISP2 may be formed in the first trenches TR1. Forming the separation patterns ISP1 and ISP2 may include performing a planarization process on the preliminary cladding layer PCL and the separation wall layer WPL until an upper surface of the first mask pattern MP1 is exposed and removing the preliminary cladding layer PCL and separation wall layer WPL in the second trenches TR2.

The device isolation pattern ST may be formed in the second trenches TR2. Since the second trenches TR2 have an aspect ratio relatively smaller than the first trenches TR1, a seam or a void may not be formed inside the device isolation pattern ST. A level of the upper surface of the device isolation pattern ST may be the same as or lower than a level of the upper surfaces of the first and second active patterns AP1 and AP2.

Referring to FIGS. 7A and 7B, the first capping pattern CP1 and the first mask pattern MP1 may be removed. A plurality of the first sacrificial patterns PP1 crossing the stacking patterns STP may be formed on the stacking patterns STP. Each of the first sacrificial patterns PP1 may be formed in a bar shape extending in the first direction D1. Forming the first sacrificial patterns PP1 may include forming a sacrificial layer on the upper surface of the substrate 100, forming second mask patterns MP2 on the sacrificial layer, and patterning the sacrificial layer using the second mask patterns MP2. For example, the sacrificial layer may comprise amorphous silicon and/or polysilicon.

The first protective layer PL1 may be selectively removed on the stacked patterns STP on which the first sacrificial patterns PP1 are not formed. For this reason, the upper surface of the stacking patterns STP may be exposed. On the other hand, the separation patterns ISP1 and ISP2 may not be removed.

An outer gate spacer layer OGSL may be conformally formed on the upper surface of the substrate 100. The outer gate spacer layer OGSL may cover the first sacrificial patterns PP1, the second mask patterns MP2, and the stacking patterns STP. The outer gate spacer layer OGSL may be composed of a single layer or a multilayer including different insulating materials.

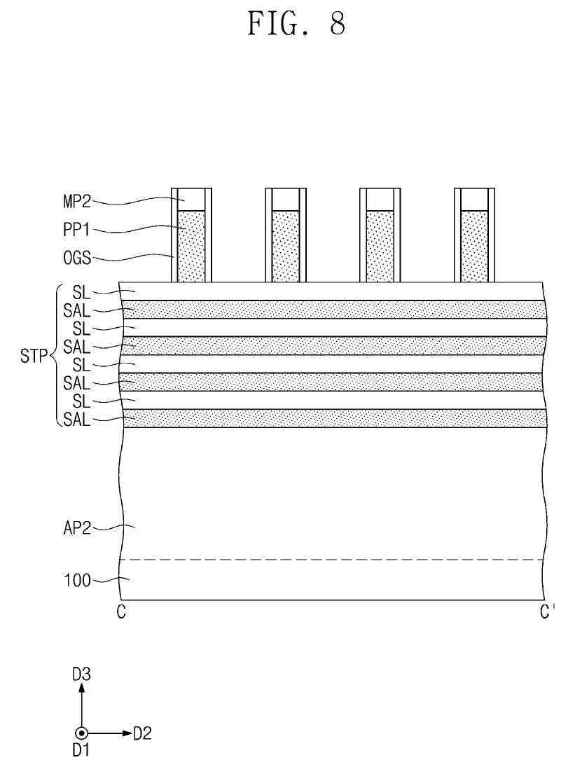

Referring to FIG. 8, the outer gate spacers OGS may be formed by performing an anisotropic etching process on the outer gate spacer layer OGSL. The outer gate spacer layer OGSL on an upper surface of the second mask pattern MP2 and an upper surface of each of the stacking patterns STP may be removed by the etching process. The outer gate spacers OGS may cover a sidewall of the second mask patterns MP2 and a sidewall of first sacrificial patterns PP1.

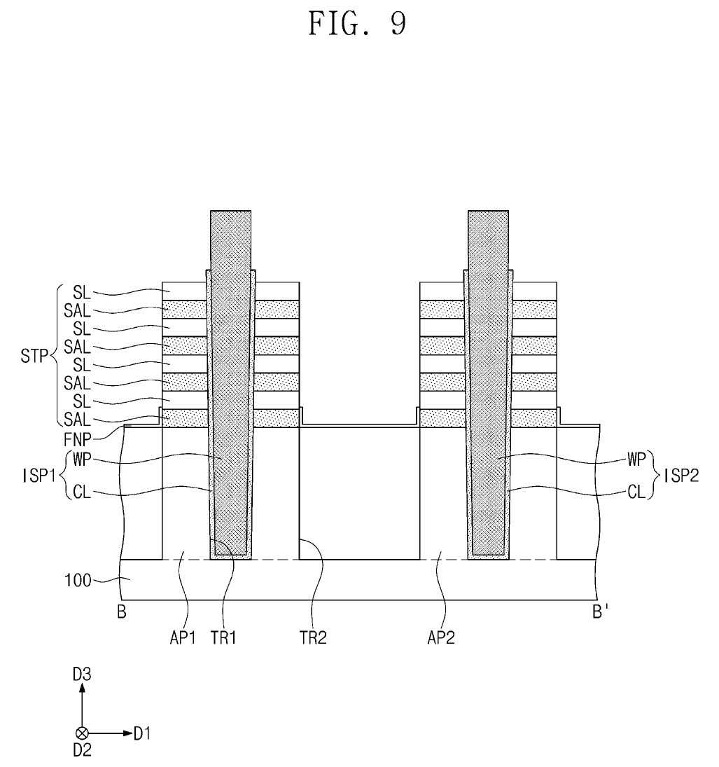

Referring to FIG. 9, a trim process may be performed on the separation patterns ISP1 and ISP2 on the substrate 100 on which the first sacrificial patterns PP1 are not formed. For this reason, a portion of the cladding pattern CL on the upper portions of the separation patterns ISP1 and ISP2 may be removed. A level of the upper surface of the cladding pattern CL may be lower than a level of the upper surface of the separation wall patterns WP. In some embodiments, the level of the upper surface of the cladding pattern CL may be lower than a level of the upper surface of the stacking patterns STP.

The outer gate spacer OGS on the stacking patterns STP may be removed by the trim process. However, a portion of the outer gate spacer OGS adjacent to the device isolation pattern ST and a lower portion of the stacking patterns STP may remain to form the fence portion FNP. The fence portion FNP may be a portion of the outer gate spacer OGS.

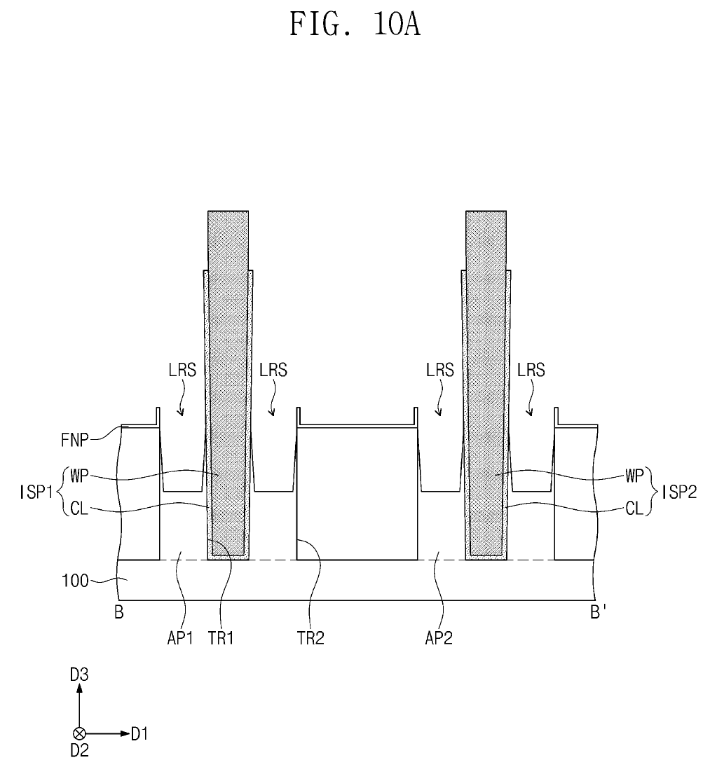

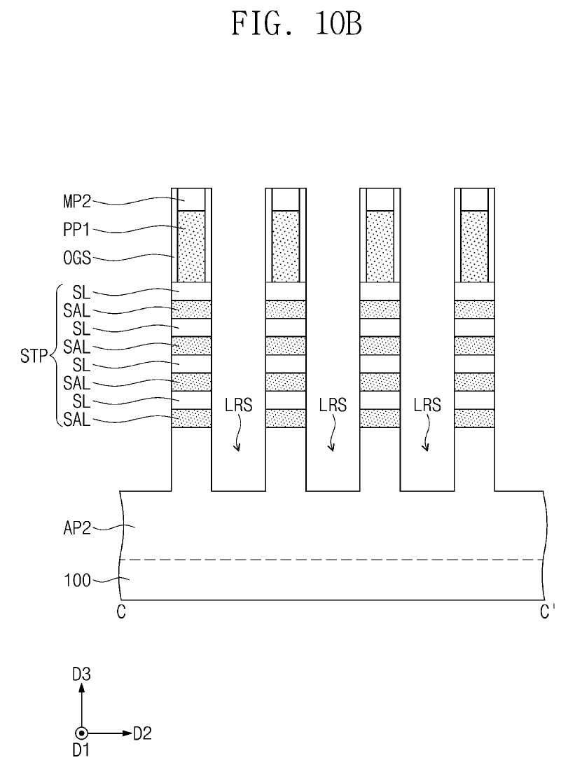

Referring to FIGS. 10A and 10B, an etching process using the outer gate spacers OGS and the second mask patterns MP2 as a mask may be performed. The etching process may remove a portion of the stacking patterns STP and a portion of the first and second active patterns AP1 and AP2. Due to the etching process, the lower recesses LRS may be formed between the first sacrificial patterns PP1 adjacent to each other in the second direction D2. The stacking patterns STP may have a shape extending in the third direction D3 by the lower recesses LRS. A bottom surface of the lower recesses LRS may be lower than the upper surface of the device isolation pattern ST.

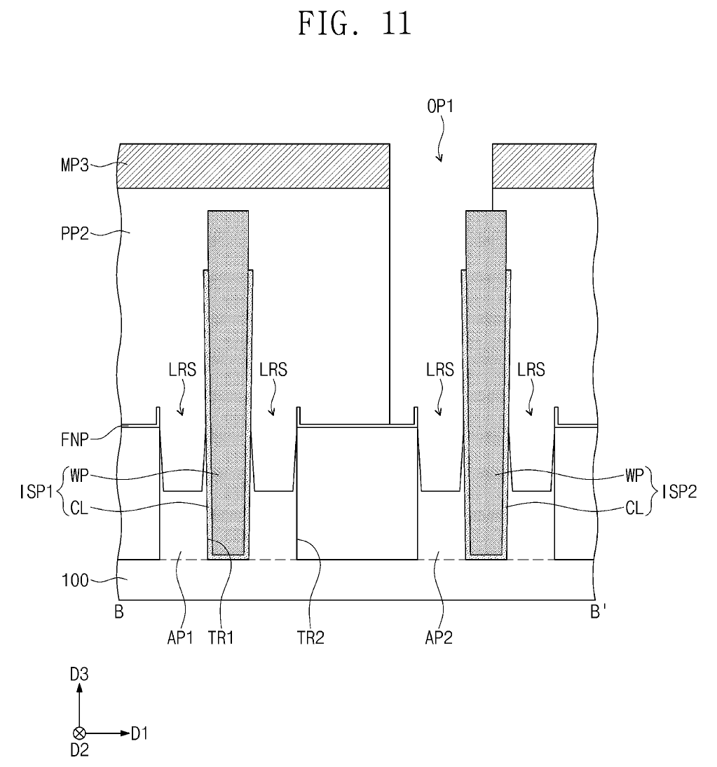

Referring to FIG. 11, second sacrificial patterns PP2 may be formed on the upper surface of the substrate 100. The second sacrificial patterns PP2 may include amorphous silicon and/or polysilicon. A third mask pattern MP3 may be formed on the second sacrificial patterns PP2. The third mask pattern MP3 may be formed in a region excluding a region where the second source/drain patterns SD2 are to be formed (see FIG. 12A). For example, the third mask pattern MP3 may be formed on the first active pattern AP1. The third mask pattern MP3 may not be formed on a region where the embedded portion EP of FIG. 2B is to be formed. The third mask pattern MP3 may include a material having an etching selectivity with respect to the second sacrificial patterns PP2.

A portion of the second sacrificial patterns PP2 may be etched by performing an etching process using the third mask pattern MP3 as a mask. As a result, the first opening OP1 exposing the lower recess LRS of the second active pattern AP2 may be formed.

Referring to FIGS. 12A and 12B, the second source/drain patterns SD2 may be formed on the exposed second active pattern AP2. Forming the second source/drain patterns SD2 may include forming the contact sacrificial pattern PH in the lower recess LRS, forming the seed pattern SE, and performing a selective epitaxial growth process with the seed pattern SE as a seed layer.

The contact sacrificial pattern PH may include a material having an etch selectivity with respect to the second active pattern AP2. For example, the contact sacrificial pattern PH may be formed in an epitaxial growth process and may include silicon-germanium. While performing the selective epitaxial growth process with the seed pattern SE as the seed layer, n-type impurities may be injected in-situ into the second source/drain patterns SD2. In some embodiments, impurities may be implanted after the second source/drain patterns SD2 are formed.

An upper surface of the second source/drain pattern SD2 may be at a lower level than the upper surface of the second separation pattern ISP2. The upper surface of the second source/drain pattern SD2 may be higher than the upper surface of the cladding pattern CL, but is not limited thereto.

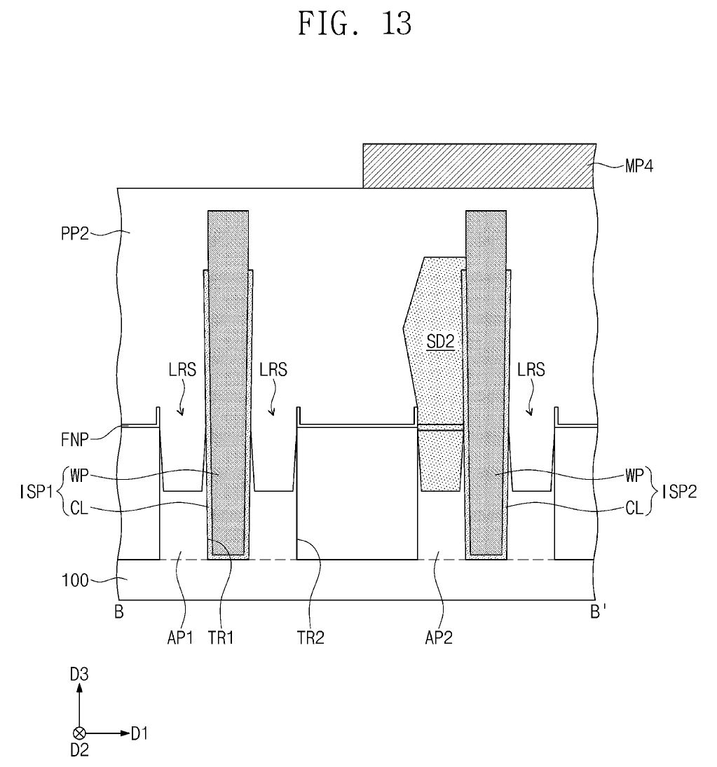

Referring to FIG. 13, the second sacrificial patterns PP2 may be formed again on the second source/drain pattern SD2. A fourth mask pattern MP4 may be formed on the second sacrificial patterns PP2. The fourth mask pattern MP4 may be formed in a region excluding a region where the first source/drain patterns SD1 are to be formed (see FIG. 15). For example, the fourth mask pattern MP4 may be formed on the second active pattern AP2. The fourth mask pattern MP4 may include a material having an etch selectivity with respect to the second sacrificial patterns PP2.

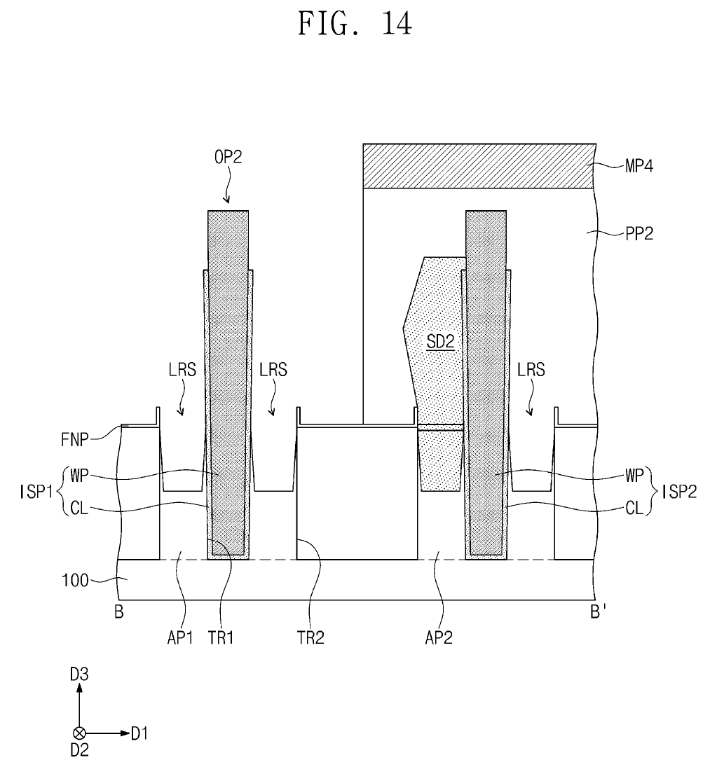

Referring to FIG. 14, a portion of the second sacrificial patterns PP2 may be etched by performing an etching process using the fourth mask pattern MP4 as a mask. As a result, a second opening OP2 exposing the lower recesses LRS of the first active pattern AP1 may be formed. The first separation pattern ISP1 between the first active patterns AP1 may be exposed by the second opening OP2.

Referring to FIGS. 15, 16A, and 16B, the first source/drain patterns SD1 may be formed on the exposed first active pattern AP1. Forming the first source/drain patterns SD1 may include forming the contact sacrificial pattern PH in the lower recess LRS, forming the seed pattern SE, and performing a selective epitaxial growth process with the seed pattern SE as a seed layer.

Forming the first source/drain patterns SD1 may be substantially the same as forming the second source/drain patterns SD2. However, while performing the selective epitaxial growth process with the seed pattern SE as the seed layer, p-type impurities may be injected in-situ into the first source/drain patterns SD1. In some embodiments, impurities may be implanted after the first source/drain patterns SD1 are formed.

The upper surface of the first source/drain pattern SD1 may be at a lower level than the upper surface of the second separation pattern ISP1. For this reason, the first source/drain patterns SD1 adjacent to each other in the first direction D1 may be spaced apart by the first separation pattern ISP1. The upper surface of the first source/drain pattern SD1 may be higher than the upper surface of the cladding pattern CL, but is not limited thereto.

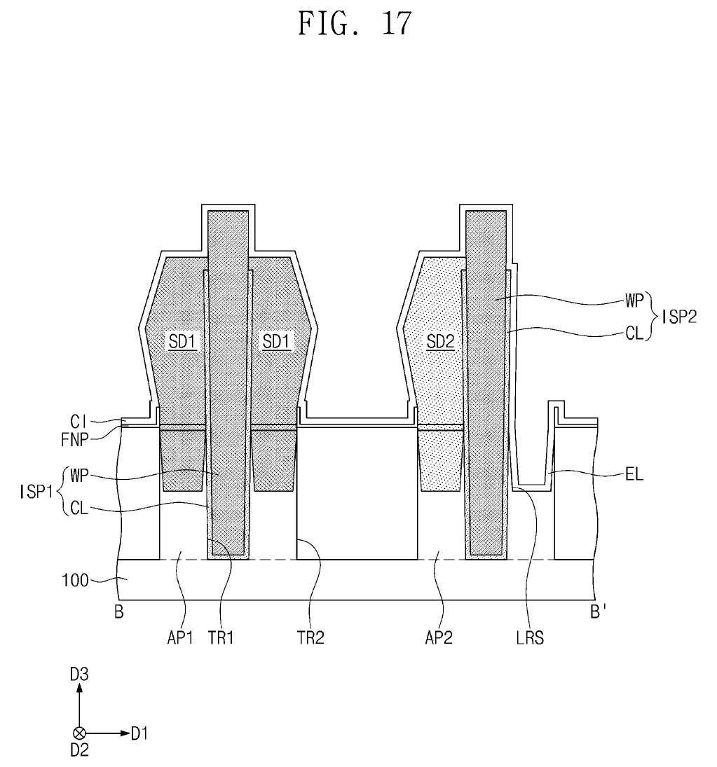

Referring to FIG. 17, the second sacrificial pattern PP2 and the fourth mask pattern MP4 on the substrate 100 may be removed. As a result, the separation patterns ISP1 and ISP2 and the first and second source/drain patterns SD1 and SD2 may be exposed. A capping insulating layer CI may be formed on the separation patterns ISP1 and ISP2 and the first and second source/drain patterns SD1 and SD2. The capping insulating layer CI may cover the fence portion FNP.

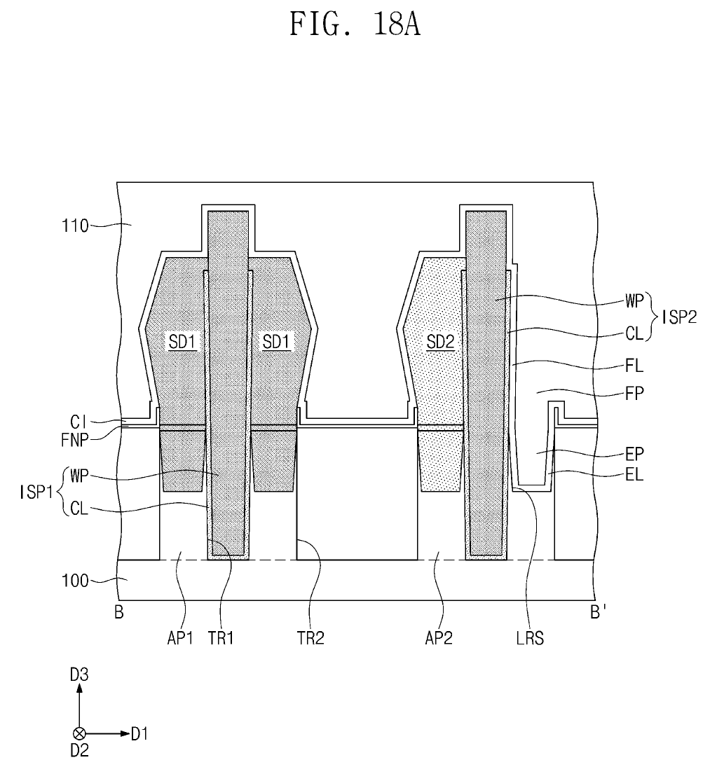

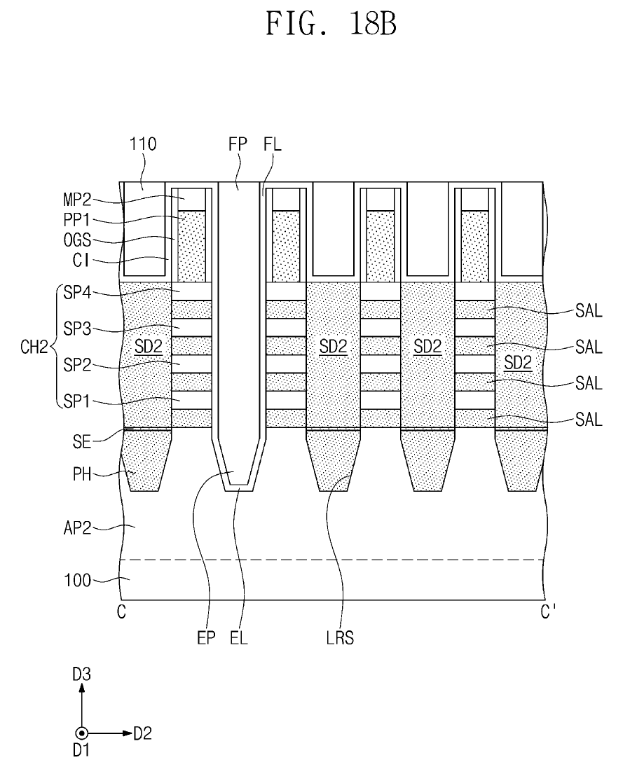

Referring to FIGS. 18A and 18B, the capping insulating layer CI may cover the outer gate spacer OGS and the second mask pattern MP2. The capping insulating layer CI may conformally cover the inner wall of the lower recess LRS of the cutting region CTR. An inner portion of the capping insulating layer CI in the lower recess LRS may be the embedded layer EL, and a portion of the capping insulation layer CI extending along the sidewall of the cladding pattern CL may be a filling layer FL.

The first interlayer insulating layer 110 may be formed on the capping insulating layer CI. The first interlayer insulating layer 110 may fill the remaining portion of the lower recess LRS of the cutting region CTR. A portion of the first interlayer insulating layer 110 in the lower recess LRS may be the embedded portion EP, and a portion of the first interlayer insulating layer 110 on the sidewall of the second separation pattern ISP2 may be the filling portion FP. The filling portion FP may be a portion of the first interlayer insulating layer 110 interposed between the stacking patterns STP. Thereafter, a planarization process may be performed on the first interlayer insulating layer 110 until an upper surface of the capping insulating layer CI is exposed.

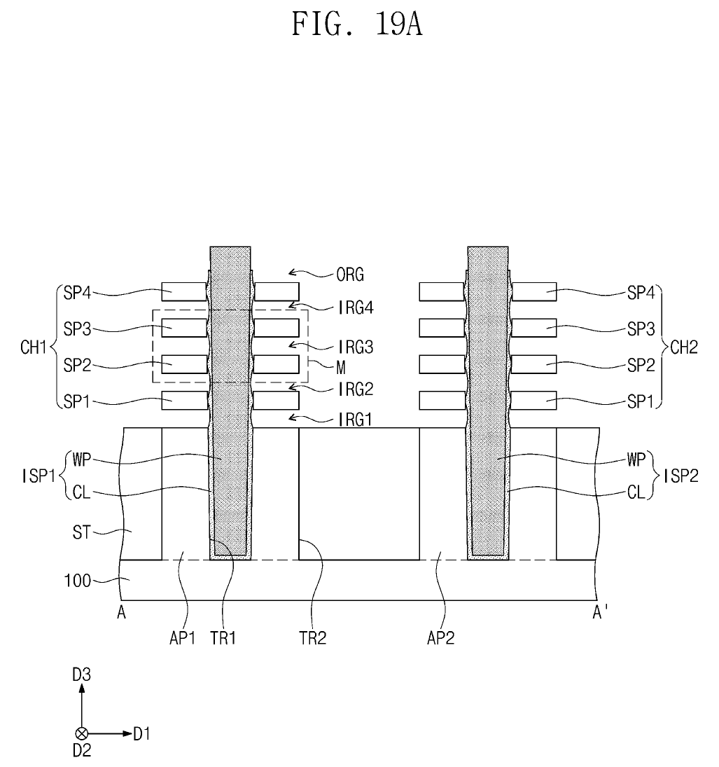

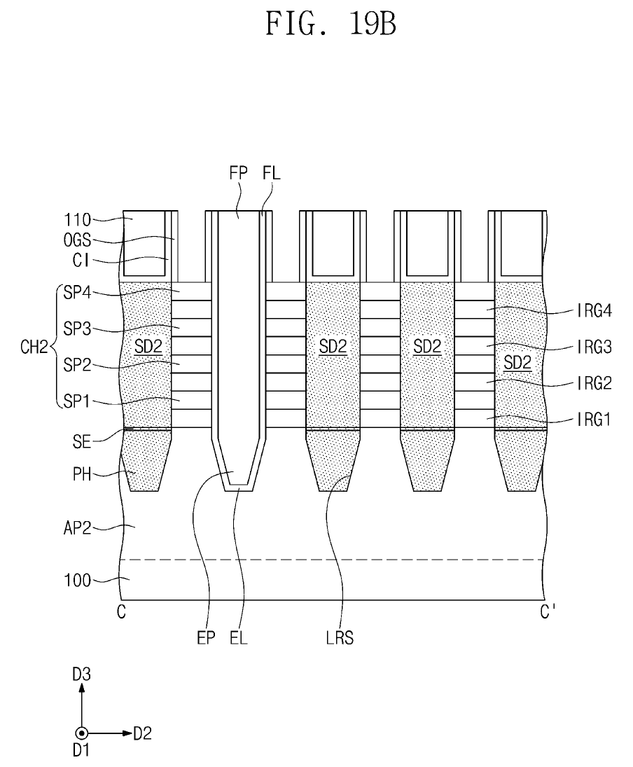

Referring to FIGS. 19A and 19B, a planarization process for the first interlayer insulating layer 110 may be performed until upper surfaces of the first sacrificial patterns PP1 are exposed. The second mask patterns MP2 on the first sacrificial patterns PP1 may be removed together by the planarization process. Therefore, the upper surface of the first interlayer insulating layer 110 may be coplanar with the upper surfaces of the first sacrificial patterns PP1, the upper surfaces of a capping insulating layer CI, and an upper surfaces of the outer gate spacers OGS.

The exposed first sacrificial patterns PP1 may be selectively removed. Removing the first sacrificial patterns PP1 may include a wet etch process using an etchant that selectively removes polysilicon. By removing the first sacrificial patterns PP1, an outer region ORG may be formed. Due to the outer region ORG, the stacking patterns STP may be exposed to the outside.

The sacrificial layers SAL of the stacking patterns STP exposed through the outer region ORG may be selectively removed. The sacrificial layers SAL may be selectively removed to form first to fourth inner regions IRG1, IRG2, IRG3, and IRG4. The etching process of selectively removing the sacrificial layers SAL may remove only the sacrificial layers SAL while remaining the semiconductor layers SL. The etching process of removing the sacrificial layers SAL may have a high etch rate for silicon-germanium. Thus, a channel pattern of the logic transistor may be formed from the semiconductor layers SL. For example, the first and second channel patterns CH1 and CH2 including the first to fourth semiconductor patterns SP1, SP2, SP3, and SP4 may be formed.

Referring to FIG. 20, the cladding pattern CL of the separation patterns ISP1 and ISP2 may be exposed through the first to fourth inner regions IRG1, IRG2, IRG3, and IRG4. A portion of the cladding pattern CL may also be removed while the sacrificial layers SAL are etched. The second portion PT2 of the cladding pattern CL, which is an exposed portion, may be relatively more etched than the first portion PT1 of the cladding pattern CL interposed between the separation wall pattern WP and the first and second channel patterns CH1 and CH2. Therefore, an average width of the first portion PT1 may be greater than an average width of a second portion PT2. The first width W1 of the first portion PT1 in the first direction D1 may be smaller than the second width W2 of the second portion PT2 in the first direction D1.

Since the middle portion of the first portion PT1 is etched relatively less than the edge portion of the first portion PT1, the width of the middle portion of first portion PT1 may be greater than the width of the edge portion of first portion PT1. Because the middle portion of the second portion PT2 is etched relatively more than the edge portion of the second portion PT2, the width of the middle portion of second portion PT2 may be smaller than the width of the edge portion of second portion PT2.

Thereafter, the gate insulating layer GI may be formed to have a uniform thickness in the first to fourth inner regions IRG1, IRG2, IRG3, and IRG4 and the outer region ORG. The gate insulating layer GI may cover the first to fourth semiconductor patterns SP1, SP2, SP3, and SP4, the separation patterns ISP1 and ISP2, and the device isolation pattern ST.

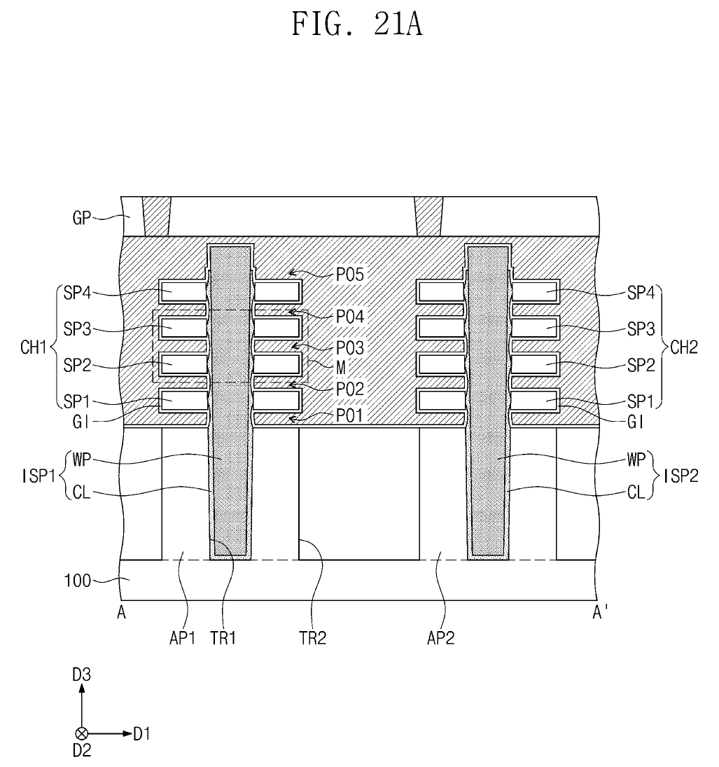

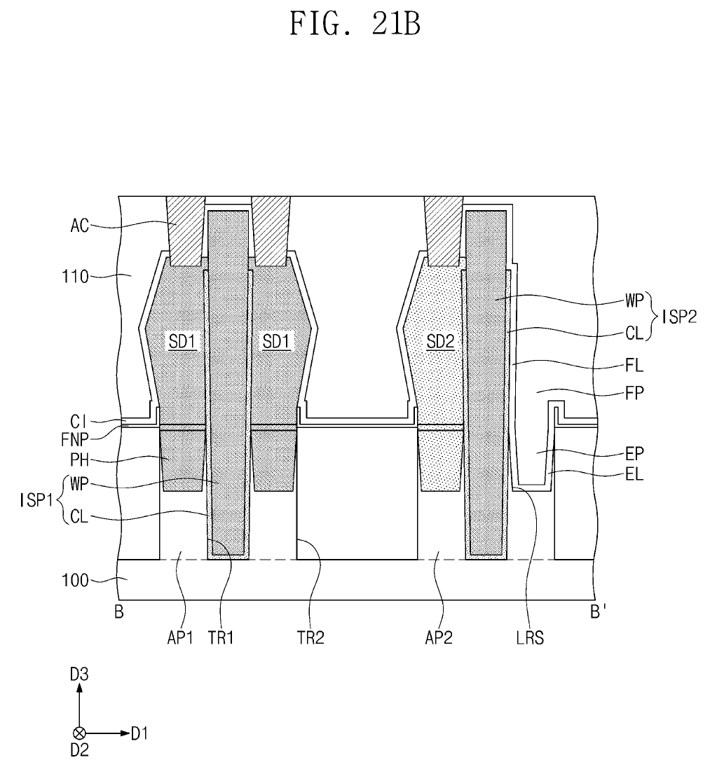

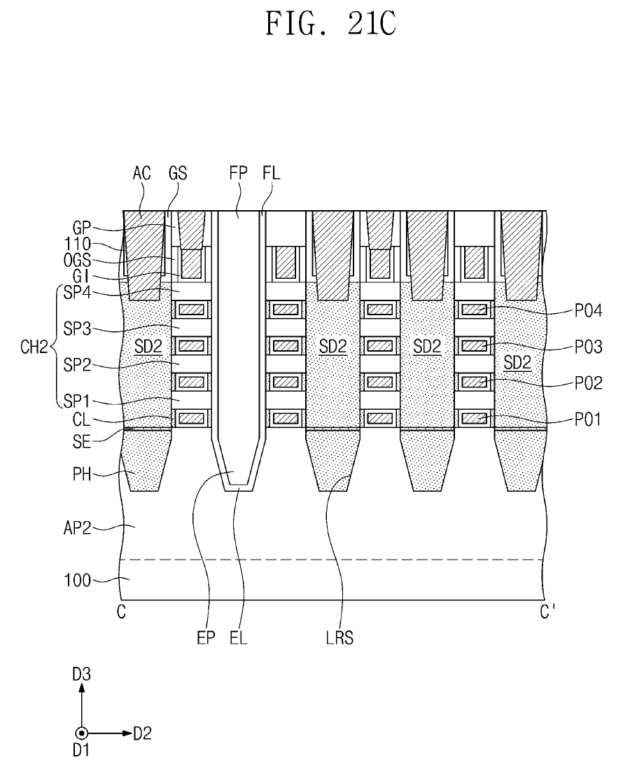

Referring to FIGS. 21A, 21B, and 21C, the first and second gate electrodes GE1 and GE2 may be formed on the gate insulating layer GI. Forming the first and second gate electrodes GE1, GE2 may include forming the first to fourth inner electrodes PO1, PO2, PO3, PO4 between the first to fourth semiconductor patterns SP1, SP2, SP3, SP4 and forming the outer electrode PO5 in the outer region ORG.

The gate capping patterns GP may be formed on the first and second gate electrodes GE1 and GE2. A planarization process may be performed on the gate capping patterns GP such that the upper surfaces of the gate capping pattern GP are coplanar with the upper surface of the first interlayer insulating layer 110.

Thereafter, the cutting patterns CT penetrating through the first and second gate electrodes GE1 and GE2 may be formed. The cutting patterns CT may extend from the gate capping patterns GP to the device isolation pattern ST. Due to the cutting patterns CT, the first and second gate electrodes GE1 and GE2 may be spaced apart from each other in the first direction D1.

The cladding pattern CL may be an inner gate spacer. The cladding pattern CL may be interposed between the separation wall pattern WP and the first to fourth semiconductor patterns SP1, SP2, SP3, and SP4. Therefore, the cladding pattern CL can prevent leakage current generated from the first to fourth semiconductor patterns SP1, SP2, SP3, and SP4. Accordingly, the electrical characteristics of the semiconductor element can be improved.

The active contacts AC may be formed in the first interlayer insulating layer 110. Each of the active contacts AC may penetrate the first interlayer insulating layer 110 to be connected to at least one of the first and second source/drain patterns SD1 and SD2.

The gate contacts GC may be formed in the gate capping patterns GP. Each of the gate contacts GC may be connected to the first and second gate electrodes GE1 and GE2 through the gate capping patterns GP.

Referring again to FIGS. 2A, 2B, 2C, and 3A, a second interlayer insulating layer 120 may be formed on the first interlayer insulating layer 110. The upper vias UV may be formed in the second interlayer insulating layer 120. The upper vias UV may penetrate the second interlayer insulating layer 120 to be connected to the active contacts AC and the gate contacts GC.

According to the method for manufacturing a semiconductor device, the cutting region CTR in which the second source/drain pattern SD2 is not formed may be formed on the second active pattern AP2. The embedded layer EL and the embedded portion EP may be formed in the lower recess LRS instead of the second source/drain pattern SD2 on the cutting region CTR. The embedded layer EL may be part of the capping insulating layer CI, and the embedded portion EP may be part of a first interlayer insulating layer 110.

Instead of cutting the first and second active patterns AP1 and AP2 by etching the separation patterns ISP1 and ISP2, the first and second source/drain patterns SD1 and SD2 are not formed, so that the first and second active patterns AP1 and AP2 may be separated. For this reason, the separation patterns ISP1 and ISP2 may be prevented from being etched relatively much (e.g., over-etched), and the first sacrificial pattern PP1 on the separation pattern ISP1 and the ISP2 may be prevented from growing epitaxially together when the first and second source/drain patterns SD1 and SD2 are formed to meet the first and second sources/drain patterns SD1 and SD2. As a result, a semiconductor element with improved electrical characteristics and reliability may be manufactured by preventing electrical short circuit.

The semiconductor device according to embodiments may cut the active patterns by not forming the source/drain patterns on the active patterns. The embedded portion of the first interlayer insulating layer instead of the source/drain patterns may be formed in the lower recess. In addition, the source/drain patterns may be formed on one sidewall of the separation patterns, and the embedded layer and the embedded portion may be formed on the other sidewall of the separation patterns. This may prevent electrical shorts with the source/drain patterns adjacent to the gate electrode that occur by etching the separation patterns to cut the previously active patterns. As a result, electrical characteristics and reliability of the semiconductor device can be improved.

According to an embodiment, a method for manufacturing a semiconductor device may include forming active patterns and a separation pattern on a substrate, wherein the active patterns extend in a first direction, and the separation pattern extends vertically between the active patterns; forming lower recesses in the active patterns; forming a source/drain pattern in one of the lower recesses; and forming a capping insulating layer and an interlayer insulating layer covering the source/drain patterns, wherein the interlayer insulating layer includes an embedded portion extending into the other one of the lower recesses, wherein the separation pattern has a first sidewall and a second sidewall opposite in a second direction intersecting the first direction, and wherein the first sidewall contacts the embedded portion and the second sidewall contacts the source/drain pattern.

In the method for manufacturing a semiconductor device, the capping insulating layer includes an embedded layer covering an inner wall of the lower recesses.

In the method for manufacturing a semiconductor device, a level of a bottom surface of the embedded layer is same as a level of a bottom surface of the source/drain pattern.

In the method for manufacturing a semiconductor device, the separation pattern includes a cladding pattern and a separation wall pattern on the cladding pattern, and the cladding pattern is interposed between the separation wall pattern and the embedded portion.

The method for manufacturing a semiconductor device further may include forming first channel patterns spaced apart from each other on the active patterns, and the interlayer insulating layer further includes a filling portion on the embedded portion, where the filling portion is interposed between the first channel patterns.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device comprising:
active patterns on a substrate and spaced apart in a first direction;
at least one source/drain pattern on at least a first active pattern of the active patterns;
an interlayer insulating layer covering the at least one source/drain pattern; and
a separation pattern between the active patterns and extending in a second direction intersecting the first direction,
wherein the interlayer insulating layer comprises an embedded portion extending into the first active pattern of the active patterns,
wherein the separation pattern comprises a first sidewall and a second sidewall opposite to the first sidewall in the first direction, and
wherein the first sidewall contacts the embedded portion and the second sidewall contacts the at least one source/drain pattern.

2. The semiconductor device of claim 1, further comprising a capping insulating layer on the at least one source/drain pattern,
wherein the capping insulating layer comprises an embedded layer between the embedded portion and the first active pattern.

3. The semiconductor device of claim 2, wherein a bottom surface of the embedded layer is at a level that is the same as a level of a bottom surface of the at least one source/drain pattern.

4. The semiconductor device of claim 2, wherein a width of the embedded portion decreases in a vertical direction toward a bottom surface of the substrate, and
wherein a thickness of the embedded layer is in a range of 3 nm to 10 nm.

5. The semiconductor device of claim 2, wherein the separation pattern comprises a cladding pattern and a separation wall pattern on the cladding pattern, and
wherein the cladding pattern is between the separation wall pattern and the embedded portion.

6. The semiconductor device of claim 5, wherein the cladding pattern is between the separation wall pattern and the embedded layer, and
wherein at least a portion of the embedded layer contacts the cladding pattern.

7. The semiconductor device of claim 5, further comprising a first channel pattern adjacent to the separation pattern; and
a gate electrode extending in the first direction on the first channel pattern,
wherein the cladding pattern comprises:
a first portion between the separation wall pattern and the first channel pattern; and
a second portion between the separation wall pattern and the gate electrode, and
wherein a width of the first portion is greater than a width of the second portion in the first direction.

8. The semiconductor device of claim 2, further comprising first channel patterns on the first active pattern and spaced apart in the second direction,
wherein the interlayer insulating layer comprises a filling portion on the embedded portion, and
wherein the filling portion is between the first channel patterns.

9. The semiconductor device of claim 8, wherein the separation pattern comprises a cladding pattern and a separation wall pattern on the cladding pattern,
wherein the capping insulating layer comprises a filling layer on the embedded layer,
wherein the filling layer is between the filling portion and the separation pattern, and
wherein the filling layer covers a sidewall of the cladding pattern.

10. The semiconductor device of claim 9, wherein the filling layer is between the first channel patterns and the filling portion, and
wherein the filling layer contacts sidewalls of the first channel patterns and the cladding pattern.

11. The semiconductor device of claim 9, wherein the at least one source/drain pattern comprises a first source/drain pattern adjacent to the filling layer, a second source/drain pattern adjacent to the first source/drain pattern and spaced apart from the filling layer in the second direction,
wherein, in the second direction, a first interval between the filling layer and the first source/drain pattern is the same as a second interval between the first source/drain pattern and the second source/drain pattern.

12. A semiconductor device comprising:
an active pattern on a substrate;
a source/drain pattern on the active pattern;
a capping insulating layer covering the source/drain pattern;
an interlayer insulating layer on the capping insulating layer; and
a separation pattern on the substrate and extending in a first direction,
wherein the interlayer insulating layer comprises an embedded portion extending into the active pattern,
wherein the capping insulating layer comprises an embedded layer between the embedded portion and the separation pattern, and
wherein a bottom surface of the embedded layer is at a level that is the same as a level of a bottom surface of the source/drain pattern.

13. The semiconductor device of claim 12, wherein a width of the embedded portion decreases in the first direction toward a bottom surface of the substrate.

14. The semiconductor device of claim 12, wherein the embedded layer extends between the embedded portion and the active pattern, and
wherein a thickness of the embedded layer is in a range of 3 nm to 10 nm.

15. The semiconductor device of claim 12, wherein the separation pattern comprises a cladding pattern and a separation wall pattern on the cladding pattern, and
wherein the cladding pattern is between the separation wall pattern and the embedded portion.

16. The semiconductor device of claim 15, wherein the cladding pattern is between the separation wall pattern and the embedded layer, and
wherein at least a portion of the embedded layer contacts the cladding pattern.

17. A semiconductor device comprising:
a substrate comprising an active pattern;
a device isolation pattern defining the active pattern;
at least one first channel pattern and a second channel pattern on the active pattern and spaced apart in a first direction;
a first source/drain pattern and a second source/drain pattern respectively connected to the at least one first channel pattern and the second channel pattern;
a separation pattern on the substrate and extending in a second direction intersecting the first direction;
a gate electrode on the at least one first channel pattern and the second channel pattern;
a gate insulating layer between the gate electrode, the at least one first channel pattern and the second channel pattern;
a capping insulating layer covering the first source/drain pattern and the second source/drain pattern;
a gate capping pattern on an upper surface of the gate electrode;
an interlayer insulating layer covering the first source/drain pattern, the second source/drain pattern and the capping insulating layer;
an active contact connected to the first source/drain pattern and the second source/drain pattern through the interlayer insulating layer;
a gate contact connected to the gate electrode through the gate capping pattern and the interlayer insulating layer; and
a first metal layer on the interlayer insulating layer, the first metal layer comprising a first wiring connected to the active contact and the gate contact,
wherein the interlayer insulating layer comprises an embedded portion extending into the active pattern,
wherein the capping insulating layer comprises an embedded layer extending between the embedded portion and the separation pattern, and
wherein the separation pattern is between the embedded portion and the second source/drain pattern.

18. The semiconductor device of claim 17, wherein the at least one first channel pattern comprises a plurality of first channel patterns spaced apart in a third direction intersecting the first direction and the second direction,
wherein the interlayer insulating layer further comprises a filling portion on the embedded portion, and
wherein the filling portion is between the plurality of first channel patterns.

19. The semiconductor device of claim 18, wherein the separation pattern comprises a cladding pattern and a separation wall pattern on the cladding pattern,
wherein the capping insulating layer comprises a filling layer on the embedded layer,
wherein the filling layer is between the filling portion and the separation pattern, and
wherein the filling layer covers a sidewall of the cladding pattern.

20. The semiconductor device of claim 19, further comprising a third source/drain pattern,
wherein the first source/drain pattern, the second source/drain pattern, and the third source/drain pattern are spaced apart in the third direction,
wherein the second source/drain pattern is adjacent to the filling layer, and the third source/drain pattern is adjacent to the second source/drain pattern and spaced apart from the filling layer in the third direction, and
wherein a first interval between the filling layer and the second source/drain pattern in the third direction is the same as a second interval between the second source/drain pattern and the third source/drain pattern in the third direction.
